(19) United States
(12) Patent Application Publication
(10) Pub. No.: US 2026/0343993 A1
(43) Pub. Date: Oct. 29, 2026

(54) SEMICONDUCTOR DEVICE INCLUDING BACKSIDE CONTACTS

(71) Applicant: Samsung Electronics Co., Ltd., Suwon-si (KR)

(72) Inventors: Sungmoon Lee, Suwon-si (KR); Yoolim Ahn, Suwon-si (KR); Minchan Gwak, Suwon-si (KR)

(73) Assignee: Samsung Electronics Co., Ltd., Suwon-si (KR)

(21) Appl. No.: 19/639,949

(22) Filed: Apr. 6, 2026

(30) Foreign Application Priority Data
Apr. 25, 2025 (KR) 10-2025-0054740

(51) Int. Cl. H10D 64/23; H10D 84/83; H10W 20/42

(52) U.S. Cl. CPC H10D 64/254; H10D 84/832; H10W 20/422

(57) ABSTRACT

A semiconductor device includes gate lines that are neighboring one another in a first horizontal direction and each extend in a second horizontal direction, source/drain regions adjacent to the gate lines in the first horizontal direction, respectively, a backside via contact connected to a pair of source/drain regions facing one another in the second horizontal direction, backside insulating patterns aligned with the gate lines in a vertical direction and spaced apart from one another in the first horizontal direction, semiconductor blocks contacting sidewalls of the backside insulating patterns, and a device isolation layer covering sidewalls of the backside via contact, wherein the backside via contact includes a pair of first portions that face the pair of source/drain regions, and a second portion between the pair of first portions, and a first horizontal width of the pair of first portions is less than a second horizontal width of the second portion.

### CROSS-REFERENCE TO RELATED APPLICATIONS

This present application claims priority to and the benefit under 35 U.S.C. § 119(a)-(d) of Korean Patent Application No. 10-2025-0054740, filed on Apr. 25, 2025, in the Korean Intellectual Property Office, the entire disclosure of which is incorporated herein by reference.

### FIELD

The disclosed concepts relate to a semiconductor device and a method of manufacturing the same, and more particularly, to a semiconductor device including backside contacts and a method of manufacturing the semiconductor device.

### BACKGROUND

With advances in electronics, the downscaling of semiconductor devices has been rapidly processing. In highly downscaled semiconductor devices, not only high operation speed but also operational accuracy is required, and thus, it is necessary to provide a wiring structure that includes conductive lines having a stable and optimized arrangement in a relatively small area.

### SUMMARY

The disclosed concepts provide a semiconductor device with improved functional reliability and a method of manufacturing the same.

According to aspects of the disclosed concepts, there is provided a semiconductor device including a plurality of gate lines that are neighboring one another in a first horizontal direction and each extend in a second horizontal direction substantially perpendicular to the first horizontal direction, a plurality of source/drain regions arranged adjacent to the plurality of gate lines in the first horizontal direction, respectively, a backside via contact connected to a pair of source/drain regions that face one another in the second horizontal direction among the plurality of source/drain regions, a plurality of backside insulating patterns aligned with the plurality of gate lines in a vertical direction and spaced apart from one another in the first horizontal direction, a plurality of semiconductor blocks contacting sidewalls of the plurality of backside insulating patterns in the first horizontal direction, and a device isolation layer covering sidewalls of the backside via contact in the second horizontal direction, wherein the backside via contact includes a pair of first portions that face the pair of source/drain regions, and a second portion arranged between the pair of first portions, and a first horizontal width of the pair of first portions in the first horizontal direction is less than a second horizontal width of the second portion in the first horizontal direction.

According to aspects of the disclosed concepts, there is provided a semiconductor device including a plurality of gate lines that are neighboring one another in a first horizontal direction and each extend in a second horizontal direction substantially perpendicular to the first horizontal direction, a plurality of source/drain regions arranged adjacent to the plurality of gate lines in the first horizontal direction, respectively, a first backside via contact connected to a first pair of source/drain regions that face one another in the second horizontal direction among the plurality of source/drain regions, a second backside via contact spaced apart from the first backside via contact in the first horizontal direction and connected to a second pair of source/drain regions that face one another in the second horizontal direction among the plurality of source/drain regions, a plurality of backside insulating patterns aligned with the plurality of gate lines in a vertical direction, a plurality of semiconductor blocks contacting sidewalls of the plurality of backside insulating patterns in the first horizontal direction, and a device isolation layer covering sidewalls of the backside via contact in the second horizontal direction, wherein the first backside via contact includes a pair of first portions facing the first pair of source/drain regions, and a second portion arranged between the first pair of source/drain regions, and a first horizontal width of the pair of first portions in the first horizontal direction is less than a second horizontal width of the second portion in the first horizontal direction.

According to aspects of the disclosed concepts, there is provided a semiconductor device including a plurality of gate lines that are neighboring one another in a first horizontal direction and each extend in a second horizontal direction substantially perpendicular to the first horizontal direction, a plurality of source/drain regions arranged adjacent to the plurality of gate lines in the first horizontal direction, respectively, a backside via contact connected to any one pair of source/drain regions that face one another in the second horizontal direction among the plurality of source/drain regions, a frontside contact connected to one selected from among the plurality of source/drain regions, a plurality of backside insulating patterns aligned with the plurality of gate lines in a vertical direction and spaced apart from one another in the first horizontal direction, a plurality of semiconductor blocks contacting sidewalls of the plurality of backside insulating patterns in the first horizontal direction, and a device isolation layer covering sidewalls of the backside via contact in the second horizontal direction, wherein the backside via contact includes a pair of first portions that face the pair of source/drain regions, and a second portion arranged between the pair of first portions, and a first horizontal width of the pair of first portions in the first horizontal direction is less than a second horizontal width of the second portion in the first horizontal direction.

According to aspects of the disclosed concepts, there is provided a method of manufacturing a semiconductor device, the method including forming a sacrificial layer on a substrate and forming, on the sacrificial layer, a stack structure in which a plurality of sacrificial semiconductor layers and a plurality of nanosheet semiconductor layers are alternately stacked; forming a plurality of fin-type active regions defining a trench by etching a portion of each of the plurality of sacrificial semiconductor layers, the plurality of nanosheet semiconductor layers, the sacrificial layer, and the substrate and replacing the sacrificial layer with an etch stop layer, forming a device isolation layer filling the trench, dividing the plurality of nanosheet semiconductor layers into a plurality of nanosheet stacks and forming a plurality of recesses, forming a plurality of source/drain regions filling the plurality of recesses, forming a gate space by removing the plurality of sacrificial semiconductor layers and forming a gate dielectric layer and a gate line within the gate space, exposing the plurality of fin-type active regions and the device isolation layer by removing the substrate from a backside surface of the substrate, forming a plurality of vertical holes by etching a portion of each of the plurality of fin-type active regions and forming a plurality of backside insulating patterns filling the plurality of vertical holes, forming a first space and a second space by etching the plurality of semiconductor blocks formed as the plurality of fin-type active regions are divided by the plurality of backside insulating patterns, wherein the first space and the second space are in communication with one another and expose a selected pair of source/drain regions among the plurality of source/drain regions, and forming a backside via contact filling the first space and the second space, wherein the backside via contact includes a pair of first portions filling the first space and a second portion filling the second space, and a first horizontal width of the pair of first portions in the first horizontal direction is less than a second horizontal width of the second portion in the first horizontal direction.

In embodiments, the pair of first portions may be in contact with the plurality of semiconductor blocks in the first horizontal direction, and the second portion may be in contact with the device isolation layer and some of the plurality of backside insulating patterns in the first horizontal direction.

In embodiments, the second portion may have a polygonal shape with rounded corners in a plan view

In embodiments, the second portion may have a polygonal shape with angled corners in a plan view.

In embodiments, the second portion may have a shape that is convex towards the outer side of the second portion as the second portion becomes farther from each of the pair of first portions in the second horizontal direction.

In embodiments, upper surfaces of the pair of first portions may be at a higher vertical level than a vertical level of an upper surface of the second portion

In embodiments, the semiconductor device may further include a frontside contact connected to one of the plurality of source/drain regions, wherein the one source/drain region connected to the frontside contact may not be included in the pair of source/drain regions connected to the backside via contact.

In embodiments, the method may further include forming a frontside contact connected to some of the plurality of source/drain regions, wherein the frontside contact may be connected to at least one of the pair of source/drain regions connected to the backside via contact.

In embodiments, the method may further include forming a frontside contact connected to some of the plurality of source/drain regions, wherein the frontside contact may be aligned with the pair of first portions of the backside via contact in the vertical direction.

In embodiments, the method may further include forming a frontside contact connected to some of the plurality of source/drain regions, wherein the frontside contact may be a contact commonly connected to the pair of source/drain regions and may be aligned with the pair of first portions and the second portion of the backside via contact in the vertical direction.

### BRIEF DESCRIPTION OF THE DRAWINGS

Embodiments will be more clearly understood from the following detailed description taken in conjunction with the accompanying drawings in which:

FIG. 1 is a plan layout diagram of a cell block of a semiconductor device, according to embodiments;

FIG. 2 is a plan layout diagram of a semiconductor device according to embodiments;

FIG. 3A is a cross-sectional view taken along a line X1-X1′ of FIG. 2; FIG. 3B is a cross-sectional view taken along a line X2-X2′ of FIG. 2;

FIG. 4A is a cross-sectional view taken along a line Y1-Y1′ of FIG. 2; FIG. 4B is a cross-sectional view taken along a line Y2-Y2′ of FIG. 2; FIG. 4C is a cross-sectional view taken along a line Y3-Y3′ of FIG. 2; FIG. 4D is a cross-sectional view taken along a line Y4-Y4′ of FIG. 2;

FIG. 5 is a plan layout diagram of a semiconductor device according to embodiments;

FIG. 6 is a plan layout diagram of a semiconductor device according to embodiments;

FIG. 7 is a plan layout diagram of a semiconductor device according to embodiments;

FIG. 8 is a plan layout diagram of a semiconductor device according to embodiments;

FIG. 9 is a plan layout diagram of a semiconductor device according to embodiments;

FIG. 10A is a cross-sectional view taken along a line X1-X1′ of FIG. 9; FIG. 10B is a cross-sectional view taken along a line X2-X2′ of FIG. 9;

FIG. 11A is a cross-sectional view taken along a line Y1-Y1′ of FIG. 9; FIG. 11B is a cross-sectional view taken along a line Y2-Y2′ of FIG. 9; FIG. 11C is a cross-sectional view taken along a line Y3-Y3′ of FIG. 9; and

FIGS. 12A to 21E are cross-sectional views for explaining respective operations of a method of manufacturing a semiconductor device, according to embodiments.

### DETAILED DESCRIPTION

Hereinafter, one or more embodiments of the disclosed concepts are described in detail with reference to the attached drawings. Like reference numerals in the drawings denote like elements, and repeated descriptions thereof are omitted.

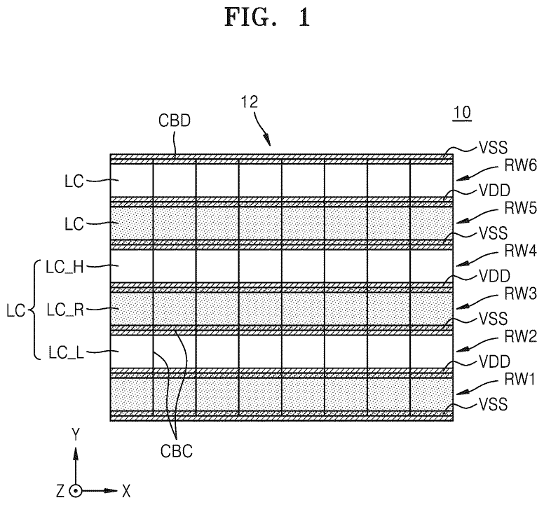

FIG. 1 is a plan layout diagram of a cell block 12 of a semiconductor device 10, according to embodiments.

Referring to FIG. 1, the cell block 12 of the semiconductor device 10 may include a plurality of logic cells LC that include circuit patterns configured to form various circuits. The logic cells LC may be arranged in a matrix form in a width direction (X direction) and a height direction (Y direction) within the cell block 12.

The logic cells LC may each include a circuit pattern having a layout designed according to a Place and Route (PnR) technique in order to perform at least one logic function. The logic cells LC may be configured to perform various logic functions. In embodiments, the logic cells LC may include a plurality of standard cells. In embodiments, at least some of the logic cells LC may perform the same logic function. In embodiments, at least some of the logic cells LC may perform different logic functions.

The logic cells LC may include a variety of logic cells that include a plurality of circuit elements. For example, each logic cell LC may include AND, NAND, OR, NOR, exclusive OR (XOR), exclusive NOR (XNOR), inverter (INV), adder (ADD), buffer (BUF), delay (DLY), filter (FIL), a multiplexer (MXT/MXIT), OR/AND/INVERTER (OAI), AND/OR (AO), AND/OR/INVERTER (AOI), D-flipflop, reset flipflop, master-slave flip-flop, latch, or a combination thereof, but is not limited thereto.

In the cell block 12, at least some of the logic cells LC forming a single row RW1, RW2, RW3, RW4, RW5, or RW6 along the width direction (X direction) may have the same width. In addition, at least some of the logic cells LC forming a single row RW1, RW2, RW3, RW4, RW5, or RW6 may have the same height. However, one or more embodiments are not limited to that shown in FIG. 1, and at least some of the logic cells LC forming a single row RW1, RW2, RW3, RW4, RW5, or RW6 may have different widths and heights.

The area of each logic cell LC included in the cell block 12 of the semiconductor device 10 may be defined by a cell boundary CBD. A cell boundary contact portion CBC may be provided between two adjacent logic cells LC that are neighboring one another in the width direction (X direction) or the height direction (Y direction) among the logic cells, where respective cell boundaries CBD of the adjacent logic cells LC meet.

In embodiments, two adjacent logic cells LC, which are neighboring one another in the width direction (X direction) in the logic cells LC forming a single row RW1, RW2, RW3, RW4, RW5, or RW6 may contact one another at the cell boundary contact portion CBC without any spacing therebetween. In embodiments, two adjacent logic cells LC, which are neighboring one another in the width direction (X direction) in the logic cells LC forming a single row RW1, RW2, RW3, RW4, RW5, or RW6, may be spaced apart from one another by a preset distance.

In embodiments, two adjacent logic cells LC, which are neighboring one another in the logic cells LC forming a single row RW1, RW2, RW3, RW4, RW5, or RW6, may perform the same function. In this case, the two adjacent logic cells LC may have the same structure. In embodiments, two adjacent logic cells LC, which are neighboring one another in the logic cells LC forming a single row RW1, RW2, RW3, RW4, RW5, or RW6, may perform different functions.

In embodiments, any one logic cell LC selected from among the logic cells LC included in the cell block 12 of the semiconductor device 10 may be symmetrical to another logic cell LC, which is adjacent to the one logic cell LC selected in the height direction (Y direction), with respect to the cell boundary contact portion CBC therebetween. For example, a reference logic cell LC_R in the third row RW3 may be symmetrical to a lower logic cell LC_L in the second row RW2 with respect to the cell boundary contact portion CBC therebetween. In addition, the reference logic cell LC_R in the third row RW3 may be symmetrical to an upper logic cell LC_H in the fourth row RW4 with respect to the cell boundary contact portion CBC therebetween.

FIG. 1 illustrates the cell block 12 including six rows RW1 to RW6, but this is only an example. The cell block 12 may include various numbers of rows selected according to necessity, and one row may include various numbers of logic cells LC selected as necessary.

One selected from among a plurality of ground lines VSS and one selected from among a plurality of power lines VDD may be arranged between the respective rows RW1 to RW6 formed of the logic cells LC that are arranged in line along the width direction (X direction). The ground lines VSS and the power lines VDD may each extend in the first horizontal direction (X direction) and may be alternately arranged apart from one another in the second horizontal direction (Y direction). Accordingly, the ground lines VSS and the power lines VDD may each be arranged to overlap the cell boundary CBD along the second horizontal direction (Y direction) of the logic cell LC.

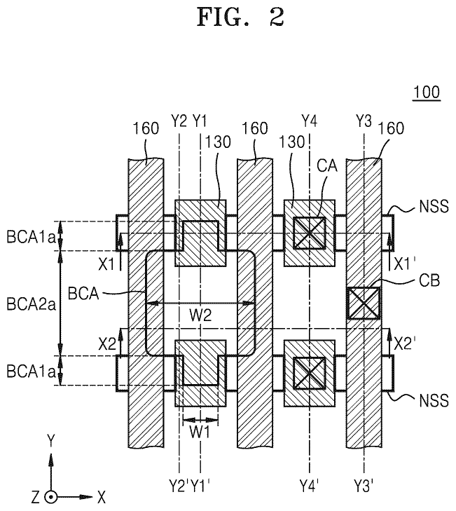

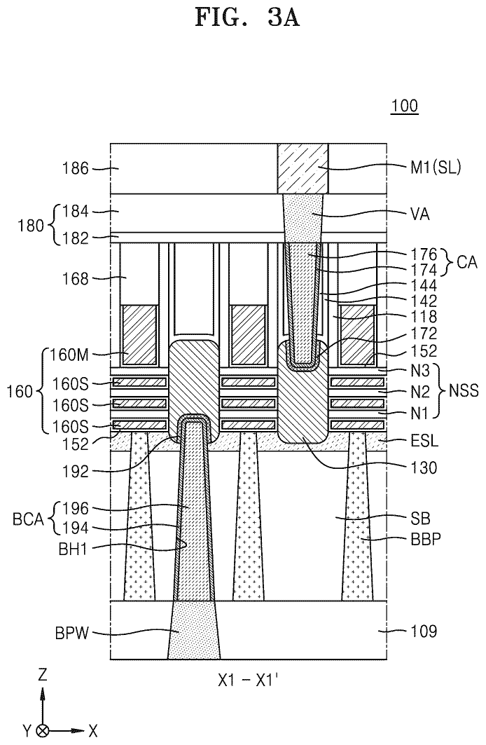

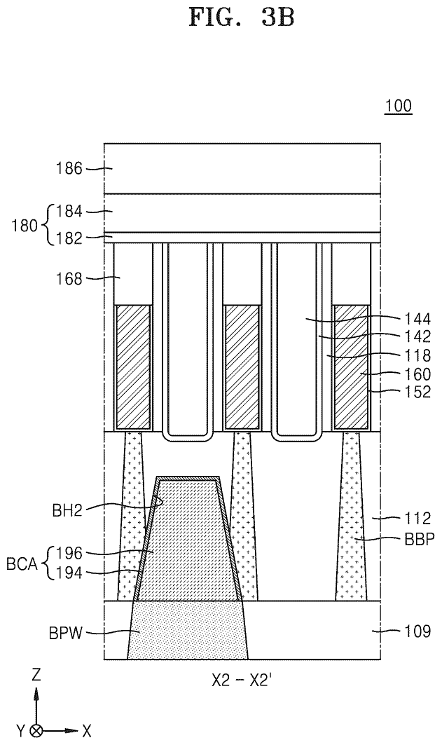

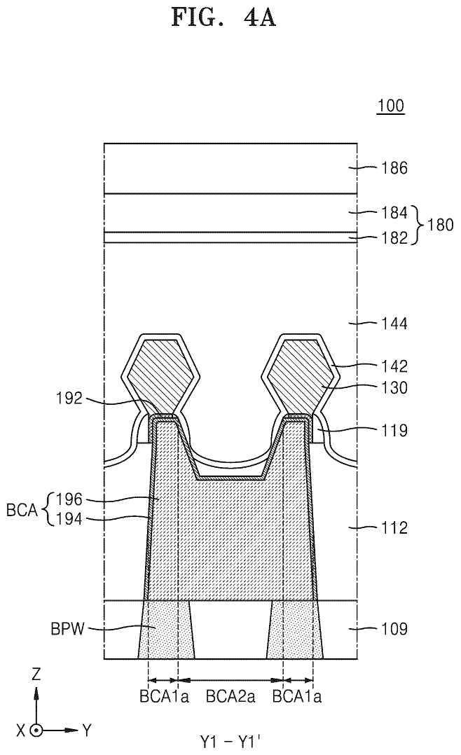

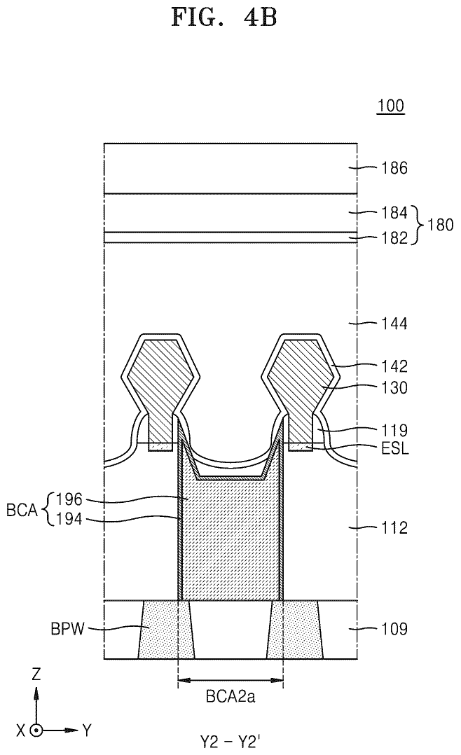

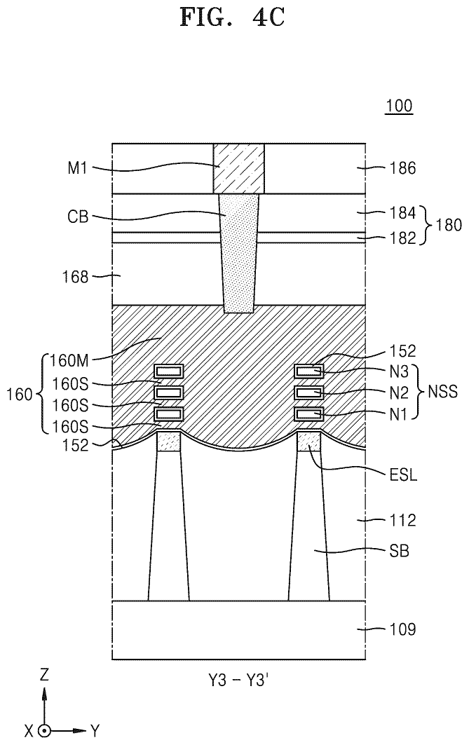

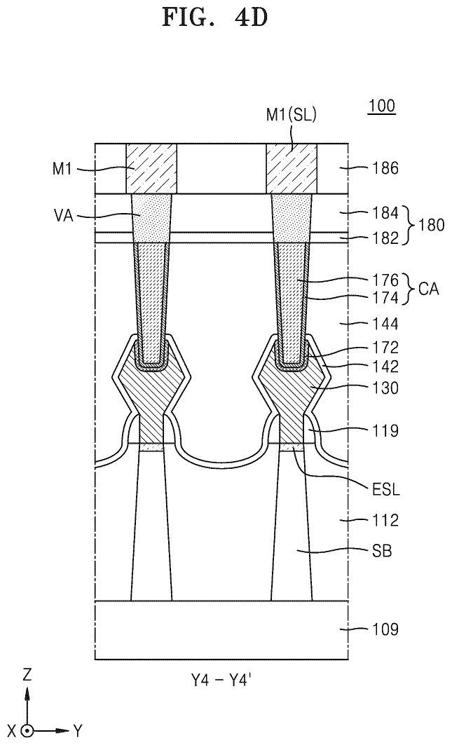

FIG. 2 is a plan layout diagram of a semiconductor device 100 according to embodiments. FIG. 3A is a cross-sectional view taken along a line X1-X1′ of FIG. 2, and FIG. 3B is a cross-sectional view taken along a line X2-X2′ of FIG. 2. FIG. 4A is a cross-sectional view taken along a line Y1-Y1′ of FIG. 2, FIG. 4B is a cross-sectional view taken along a line Y2-Y2′ of FIG. 2, FIG. 4C is a cross-sectional view taken along a line Y3-Y3′ of FIG. 2, and FIG. 4D is a cross-sectional view taken along a line Y4-Y4′ of FIG. 2. Referring to FIGS. 2 to 4D, the semiconductor device 100 including a Field Effect Transistor (FET), which has a gate-all-around structure and includes an active region in the form of a nanowire or a nanosheet and a gate surrounding the active region, is described. However, one or more embodiments are not limited thereto. Unlike the illustrations in FIGS. 2 to 4D, the semiconductor device 100 may include an FET having a fin-shaped active region and a fin structure surrounding the active region.

The semiconductor device 100 may form some of the logic cells LC shown in FIG. 1.

Referring to FIGS. 2 to 4D, the semiconductor device 100 may include a plurality of nanosheet stacks NSS, a plurality of gate lines 160 respectively surrounding the nanosheet stacks NSS, and a plurality of source/drain regions 130 each located between two adjacent gate lines 160 among the gate lines 160. The gate lines 160, the nanosheet stacks NSS, and the source/drain regions 130 may each form a plurality of nanosheet transistors.

The nanosheet stacks NSS may be arranged apart from one another in the first horizontal direction (X direction) and the second horizontal direction (Y direction) crossing the first horizontal direction (X direction). Each nanosheet stack NSS may include a first nanosheet N1, a second nanosheet N2, and a third nanosheet N3 which are sequentially stacked and spaced apart from one another in the vertical direction (Z direction). The first nanosheet N1, the second nanosheet N2, and the third nanosheet N3 included in the nanosheet stack NSS may respectively form channel regions.

The term “nanosheet” used in the present specification refers to a conductive structure having a cross-section that is substantially substantially perpendicular to a direction in which a current flows. It should be understood that the nanosheet includes a nanowire.

In the present specification, although a single nanosheet stack NSS is described as including three nanosheets, that is, the first nanosheet N1 to the third nanosheet N3, one or more embodiments are not limited thereto. For example, the number of nanosheets included in the nanosheet stack NSS may be variously selected according to necessity.

In a single nanosheet stack NSS, the first nanosheet N1 to the third nanosheet N3 may overlap one another in the vertical direction (Z direction) at positions where the first nanosheet N1 to the third nanosheet N3 are spaced apart from one another in the vertical direction (Z direction). The first nanosheet N1 to the third nanosheet N3 in a single nanosheet stack NSS may each be surrounded by one gate line 160. The first nanosheet N1 to the third nanosheet N3 in a single nanosheet stack NSS may each be used as a channel region of a nanosheet transistor.

In embodiments, the first nanosheet N1 to the third nanosheet N3 may each include a silicon (Si) layer, a silicon germanium (SiGe) layer, or a combination thereof. In embodiments, the first nanosheet N1 to the third nanosheet N3 may include the same material. In embodiments, the vertical thicknesses of the first nanosheet N1 to the third nanosheet N3 in the vertical direction (Z direction) may be the same as or similar to one another.

The gate lines 160 may be spaced apart from one another in the first horizontal direction (X direction) and extend in the second horizontal direction (Y direction). Each gate line 160 may surround the first nanosheet N1 to the third nanosheet N3 included in the nanosheet stack NSS. Each gate line 160 may be surrounded by a gate dielectric layer 152.

The gate lines 160 may surround the first nanosheet N1 to the third nanosheet N3 while covering the nanosheet stacks NSS. Each gate line 160 may include a main gate portion 160M and a plurality of sub-gate portions 160S, wherein the main gate portion 160M covers an upper surface of the nanosheet stack NSS and extends in the second horizontal direction (Y direction), and the sub-gate portions 160S are integrally connected to the main gate portion 160M and fill the spaces between the first nanosheet N1 to the third nanosheet 3 and the space below a lower surface of the first nanosheet N1. In the vertical direction (Z direction), the thickness of each sub-gate portion 160S may be less than that of the main gate portion 160M.

Each gate line 160 may include a metal, a metal nitride, a metal carbide, or a combination thereof. The metal may be selected from among titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). The metal nitride may be selected from among titanium nitride (TiN) and tantalum nitride (TaN). The metal carbide may be titanium aluminum carbide (TiAIC). However, the materials forming the gate lines 160 are not limited to the examples described above.

The gate dielectric layer 152 may be arranged between the nanosheet stack NSS and the gate line 160. The gate dielectric layer 152 may have a stack structure that includes an interface dielectric layer and a high-k dielectric layer. The interface dielectric layer may include a low-k material having a permittivity of about 9 or less, such as a silicon oxide layer, a silicon oxynitride layer, or a combination thereof. In embodiments, the interface dielectric layer may be omitted. The high-k dielectric layer may include a material with a higher dielectric constant than the silicon oxide layer. For example, the high-k dielectric layer may have a dielectric constant ranging from about 10 to about 25. The high-k dielectric layer may include hafnium oxide (HfO₂), but is not limited thereto.

Both sidewalls of each of the sub-gate portions 160S included in the gate lines 160 may be spaced apart from the source/drain region 130 with the gate dielectric layer 152 therebetween. The gate dielectric layer 152 may include: portions arranged between a sub-gate portion 160S included in the gate line 160 and each of the first nanosheet N1 to the third nanosheet N3; portions arranged between the sub-gate portion 160S included in the gate line 160 and the source/drain region 130; and a portion arranged between a sub-gate portion 160S, which is closest to the backside insulating pattern BBP among the sub-gate portions 160S of the gate lines 160, and the backside insulating pattern BBP.

Both sidewalls of the gate line 160 may be covered by a plurality of main insulating spacers 118. Each main insulating spacers 118 may cover sidewalls of the main gate portion 160M above the upper surface of the nanosheet stack NSS. Each main insulating spacer 118 may be spaced apart from the gate line 160 with the gate dielectric layer 152 therebetween.

The source/drain regions 130 may be arranged between two adjacent gate lines 160 among the gate lines 160. The source/drain regions 130 may respectively contact the first nanosheet N1, the second nanosheet N2, and the third nanosheet N3 which are included in an adjacent nanosheet stack NSS among the nanosheet stacks NSS.

Each source/drain region 130 may include a semiconductor layer including dopants. In embodiments, the semiconductor device 100 may include a nanosheet transistor including a PMOS transistor, and each source/drain region 130 may include an SiGe layer doped with p-type dopants. For example, the p-type dopant may be at least one selected from among boron (B) and gallium (Ga), but is not limited thereto.

In embodiments, the semiconductor device 100 may include a nanosheet transistor including an NMOS transistor, and each source/drain region 130 may include an Si layer doped with an n-type dopant or an SiC layer doped with n-type dopants. For example, the n-type dopant may be at least one selected from among phosphorus (P), arsenic (As), and antimony (Sb), but is not limited thereto.

Frontside surfaces of each source/drain region 130 may be covered by an insulating liner 142 and an inter-gate insulating layer 144. The frontside surfaces of each source/drain region 130 may be in contact with the insulating liner 142.

Frontside source/drain contacts CA may be connected to some of the source/drain regions 130. The frontside source/drain contact CA may penetrate an upper portion of its corresponding source/drain region 130 from the frontside surface of the source/drain region 130 in the vertical direction (Z direction).

Backside via contacts BCA may be connected to others of the source/drain regions 130. The backside via contact BCA may penetrate a lower portion of its corresponding source/drain region 130 from a backside surface of the source/drain region 130 in the vertical direction (Z direction).

In the source/drain regions 130 included in the semiconductor device 100, the source/drain region 130 connected to the backside via contact BCA may be different from that connected to the frontside source/drain contact CA. In other words, the source/drain region 130 connected to the backside via contact BCA may be spaced apart from the source/drain region 130 connected to the frontside source/drain contact CA.

A frontside metal silicide layer 172 may be arranged between the frontside source/drain contact CA and the source/drain region 130 connected to the frontside source/drain contact CA among the source/drain regions 130. The frontside source/drain contact CA may be connected to its corresponding source/drain region 130 through the frontside metal silicide layer 172.

The frontside source/drain contact CA may be configured to penetrate the inter-gate insulating layer 144 and the insulating liner 142 in the vertical direction (Z direction) and to be connected to its corresponding source/drain region 130.

The frontside source/drain contact CA may include a conductive barrier pattern 174 and a contact plug 176. The conductive barrier pattern 174 may be arranged between the frontside metal silicide layer 172 and the contact plug 176. The conductive barrier pattern 174 may include a surface contacting the frontside metal silicide layer 172 and a surface contacting the contact plug 176.

In embodiments, the conductive barrier pattern 174 may include a metal or a metal nitride. For example, the conductive barrier pattern 174 may include Ti, tantalum (Ta), W, TiN, TaN, WN, WCN, TiSiN, TaSiN, WSiN, or a combination thereof, but is not limited thereto. The contact plug 176 may include Mo, copper (Cu), W, Co, Ru, manganese (Mn), Ti, Ta, aluminum (Al), a combination thereof, or an alloy thereof, but is not limited thereto.

A backside metal silicide layer 192 may be arranged between the backside via contact BCA and the source/drain region 130 connected to the backside via contact BCA among the source/drain regions 130. The backside via contact BCA may be connected to its corresponding source/drain region 130 through the backside metal silicide layer 192.

The semiconductor device 100 may include: a plurality of backside insulating patterns BBP arranged in line along the first horizontal direction (X direction) and each extending in the second horizontal direction (Y direction); a plurality of semiconductor blocks SB; a plurality of backside via contacts BCA spaced apart one another by the backside insulating patterns BBP in the first horizontal direction (X direction); and a plurality of backside power rails BPW respectively connected to the backside via contacts BCA.

In the semiconductor device 100, the backside insulating patterns BBP may be spaced apart from the nanosheet stacks NSS in the vertical direction (Z direction).

The backside insulating patterns BBP may extend in the vertical direction (Z direction) towards one gate line 160 selected from among the gate lines 160. The backside insulating patterns BBP may include a pair of backside insulating patterns BBP that are respectively arranged on both sides of the backside via contact BCA with one backside via contact BCA therebetween in the first horizontal direction (X direction). The pair of backside insulating patterns BBP may each extend in the vertical direction (Z direction) at a position where each backside insulating pattern BBP is aligned with one selected from among the gate lines 160 in the vertical direction (Z direction). The pair of backside insulating patterns BBP may include a portion facing the backside via contact BCA in the first horizontal direction (X direction). Each backside insulating pattern BBP may contact the gate dielectric layer 152.

In embodiments, the backside insulating patterns BBP may each include a nitrogen-containing insulating layer. For example, each backside insulating pattern BBP may include an SiN layer, SiCN layer, an SiOCN layer, or a combination thereof, but one or more embodiments are not limited thereto.

Each backside via contact BCA may be connected to a single backside power rail BPW selected from among the backside power rails BPW. The backside via contacts BCA may be respectively arranged between the backside insulating patterns BBP in the first horizontal direction (X direction).

In the vertical direction (Z direction), the backside via contact BCA may extend between a pair of adjacent backside insulating patterns BBP among the backside insulating patterns BBP. The backside via contact BCA may extend in the second horizontal direction (Y direction).

The backside via contact BCA may be connected to the lower surfaces of two source/drain regions 130 that face one another in the second horizontal direction (Y direction) among the source/drain regions 130. In other words, the backside via contact BCA may be a common backside via contact that is commonly connected to the two source/drain regions 130.

Each backside via contact BCA may have a width in the first horizontal direction (X direction) that increases away from its corresponding source/drain region 130 in the vertical direction (Z direction).

The backside via contact BCA may include a conductive barrier pattern 194 and a contact plug 196. The conductive barrier pattern 194 may be between the backside metal silicide layer 192 and the contact plug 196. The conductive barrier pattern 194 may have a surface contacting the backside metal silicide layer 192 and a surface contacting the contact plug 196.

In embodiments, the conductive barrier pattern 194 may include a metal or a metal nitride. For example, the conductive barrier pattern 194 may include Ti, Ta, W, TiN, TaN, WN, WCN, TiSiN, TaSiN, WSiN, or a combination thereof, but is not limited thereto. The contact plug 196 may include Mo, Cu, W, Co, Ru, Mn, Ti, Ta, Al, a combination thereof, or an alloy thereof, but is not limited thereto.

A single backside via contact BCA may include a second portion BCA2a and a pair of first portions BCA1a, wherein the second portion BCA2a is between a pair of source/drain regions 130 that are spaced apart from one another in the second horizontal direction (Y direction), and the first portions BCA1a respectively face the lower surfaces of the pair of source/drain regions 130 with the backside metal silicide layer 192 therebetween and face one another in the second horizontal direction (Y direction) with the second portion BCA2a therebetween. The pair of first portions BCA1a may be formed in a first space BH1, and the second portion BCA2a may be formed in a second space BH2. In this case, the first space BH1 may be in communication with the second space BH2.

The pair of first portions BCA1a may respectively face the lower surfaces of the pair of source/drain regions 130 that are commonly connected to a single backside via contact BCA, with the backside metal silicide layer 192 therebetween. The pair of first portions BCA1a may contact side surfaces of a semiconductor block SB in the first horizontal direction (X direction), and the second portion BCA2a may contact a device isolation layer 112 and a backside insulating pattern BBP in the first horizontal direction (X direction).

The first portion BCA1a of the backside via contact BCA may have a square shape in a plan view, and the second portion BCA2a of the backside via contact BCA may have a square shape with rounded corners in a plan view. However, one or more embodiments are not limited thereto. The second portion BCA2a of the backside via contact BCA may have a polygonal shape with rounded corners, for example, a hexagonal shape, in a plan view.

The first portion BCA1a of the backside via contact BCA may have a first horizontal width W1, and the second portion BCA2a may have a second horizontal width W2. In embodiments, the first horizontal width W1 may be less than the second horizontal width W2.

The first portion BCA1a of the backside via contact BCA, which is arranged between a pair of adjacent backside insulating patterns BBP among the backside insulating patterns BBP, may be spaced apart from the pair of adjacent backside insulating patterns BBP in the first horizontal direction (X direction). In contrast, the second portion BCA2a of the backside via contact BCA, which is arranged between a pair of adjacent backside insulating patterns BBP among the backside insulating patterns BBP, may be in contact with the sidewalls of the pair of adjacent backside insulating patterns BBP.

The upper surface of the first portion BCA1a of the backside via contact BCA may be at a higher vertical level than the upper surface of the second portion BCA2a of the backside via contact BCA. In other words, the upper surface of the second portion BCA2a of the backside via contact BCA may be at a lower vertical level than the lower surface of the source/drain region 130 facing the first portion BCA1a of the backside via contact BCA. The term “vertical level” used in the present specification refers to a distance from the lower surface of the backside via contact BCA that is closest to the backside insulating layer 109, in the vertical direction (Z direction or −Z direction).

Some of the semiconductor blocks SB may cover the sidewalls of the backside via contact BCA in the first horizontal direction (X direction). In embodiments, some of the semiconductor blocks SB may be in contact with the sidewalls of the backside insulating pattern BBP in the first horizontal direction (X direction). Some of the semiconductor blocks SB may be between the backside insulating pattern BBP and the backside via contact BCA.

Each semiconductor block SB may include Si. The semiconductor block SB may contact the gate dielectric layer 152 covering the lowermost surface of the gate line 160. Here, the lowermost surface of the gate line 160 may refer to the surface of the gate line 160 that is closest to the backside power rail BPW.

Both sidewalls of the backside insulating pattern BBP may be covered by the device isolation layer 112 in the first horizontal direction (X direction). Both sidewalls of the backside via contact BCA may be covered by the device isolation layer 112 in the second horizontal direction (Y direction). In addition, both sidewalls of some of the semiconductor blocks SB in the second horizontal direction (Y direction) may be covered by the device isolation layer 112.

The device isolation layer 112 may have a surface facing the gate line 160 with the gate dielectric layer 152 therebetween, and a surface contacting the backside insulating pattern BBP. In addition, the device isolation layer 112 may have a surface contacting the backside via contact BCA in the second horizontal direction (Y direction), and a surface contacting the semiconductor block SB in the second horizontal direction (Y direction). The device isolation layer 112 may be an oxide layer, a nitride layer, or a combination thereof.

The backside power rail BPW may be arranged on the lower surface of the backside via contact BCA. Among the backside power rails BPW, the backside power rail BPW connected to a backside via contact BCA may be spaced apart from its corresponding source/drain region 130 in the vertical direction (Z direction), with the backside via contact BCA therebetween. The backside power rails BPW may extend in the second horizontal direction (Y direction).

Each backside power rail BPW may have a width in the first horizontal direction (X direction) that increases away from its corresponding source/drain region 130 in the vertical direction (Z direction).

An etch stop layer ESL covering the upper surface of each semiconductor block SB may be arranged on each semiconductor block SB. The etch stop layer ESL may be arranged between the upper surface of each semiconductor block SB and the gate line 160 and be in contact with the upper surface of each semiconductor block SB.

In embodiments, the etch stop layer ESL may be an insulating layer. For example, the etch stop layer ESL may include at least one selected from among SiN, SiON, SiCN, SiOC, SiOCN, and a combination thereof, but one or more embodiments are not limited thereto.

A backside insulating layer 109 may be arranged on an a terminal surface of each backside via contact BCA that is farthest from the source/drain region 130, a terminal surface of the device isolation layer 112 that is farthest from the source/drain region 130, and a terminal surface of each semiconductor block SB that is farthest from the source/drain region 130. The lower surface of each backside via contact BCA, the lower surface of the device isolation layer 112, the lower surface of each semiconductor block SB may be in contact the backside insulating layer 109. The backside insulating layer 109 may be spaced apart from the etch stop layer ESL in the vertical direction (Z direction) with each semiconductor block SB and the device isolation layer 112 therebetween.

In embodiments, the backside insulating layer 109 may include a silicon oxide layer, a silicon nitride layer, a silicon carbide layer, a low-k dielectric layer, or a combination thereof. The low-k dielectric layer may include fluorine-doped silicon oxide, organosilicate glass, carbon-doped oxide, porous silicon oxide, porous organosilicate glass, spin-on organic polymeric dielectric, spin-on silicon based polymeric dielectric, or a combination thereof, but one or more embodiments are not limited thereto.

As shown in FIGS. 4A, 4B, and 4D, a plurality of side insulating spacers 119 may be arranged on the device isolation layer 112. The side insulating spacers 119 may cover the sidewalls of the source/drain region 130. In embodiments, each side insulating spacer 119 may be integrally connected to a main insulating spacer 118 that is adjacent thereto.

The main insulating spacers 118 and the side insulating spacers 119 may each include SiN, SiO₂, SiOC, SiOCN, SiCN, SiBN, SiON, SiBCN, SiOF, SiOCH, or a combination thereof. The main insulating spacers 118 and the side insulating spacers 119 may each be a single layer including a material layer selected from among the above-listed materials, or multiple layers including multiple material layers selected from among the materials listed above.

The upper surfaces of the gate line 160 and the gate dielectric layer 152 may be respectively covered by capping insulating patterns 168. The capping insulating patterns 168 may each include a silicon nitride layer.

The source/drain regions 130, the device isolation layer 112, the main insulating spacers 118, and the side insulating spacers 119 may be covered by the insulating liner 142. The inter-gate insulating layer 144 may be arranged on the insulating liner 142. The inter-gate insulating layer 144 may be arranged between a pair of gate lines 160 that are adjacent to one another in the first horizontal direction (X direction) and between a pair of source/drain regions 130 that are adjacent to one another. In embodiments, the insulating liner 142 may include SiN, SiCN, SiBN, SiON, SiOCN, SiBCN, or a combination thereof, but one or more embodiments are not limited thereto. The inter-gate insulating layer 144 may include a silicon oxide layer, but is not limited thereto.

The frontside source/drain contact CA may be arranged over the source/drain region 130 between a pair of gate lines 160 that are adjacent to one another among the gate lines 160. A single frontside source/drain contact CA may be connected to a single source/drain region 130 or two adjacent source/drain regions 130, but one or more embodiments are not limited thereto. In the first horizontal direction (X direction), the frontside source/drain contact CA may be spaced apart from the main gate portion 160M of the gate line 160 that is adjacent to the frontside source/drain contact CA, with the main insulating spacer 118 therebetween. A frontside insulating structure including the insulating liner 142 and the inter-gate insulating layer 144 may surround the sidewalls of the frontside source/drain contact CA.

The upper surfaces of the frontside source/drain contact CA, the capping insulating patterns 168, the insulating liner 142, and the inter-gate insulating layer 144 may each be covered by the upper insulating structure 180. The upper insulating structure 180 may include an etch stop layer 182 and an upper insulating layer 184. The etch stop layer 182 may include SiC, SiN, SiCN, SiOC, AlN, AlON, AlO, AlOC, or a combination thereof. The upper insulating layer 184 may include an oxide layer, a nitride layer, an ultra-low-k (ULK) layer having an ultra-low dielectric constant ranging from about 2.2 to about 2.4, or a combination thereof. For example, the upper insulating layer 184 may include a tetraethylorthosilicate (TEOS) layer, a high density plasma (HDP) oxide layer, a boro-phospho-silicate glass (BPSG) layer, a flowable chemical vapor deposition (FCVD) oxide layer, an SiON layer, an SiN layer, an SiOC layer, an SiCOH layer, or a combination thereof, but one or more embodiments are not limited thereto.

A source/drain via contact VA may be arranged on the frontside source/drain contact CA. The source/drain via contact VA may contact the frontside source/drain contact CA by penetrating the upper insulating structure 180. Among the source/drain regions 130, the source/drain region 130 connected to the frontside source/drain contact CA may be electrically connected to the source/drain via contact VA through the frontside metal silicide layer 172 and the frontside source/drain contact CA. The source/drain via contacts VA may each include Mo or W, but are not limited thereto.

A gate contact CB may be arranged on the gate line 160. The gate contact CB may be connected to the gate line 160 by penetrating the upper insulating structure 180 and the capping insulating pattern 168 in the vertical direction (Z direction). The lower surface of the gate contact CB may be in contact with the upper surface of the gate line 160. The gate contact CB may include a contact plug including Mo, Cu, W, Co, Ru, Mn, Ti, Ta, Al, a combination thereof, or an alloy thereof, but the materials forming the contact plug are not limited thereto. In embodiments, the gate contact CB may further include a conductive barrier pattern surrounding a portion of the contact plug. The conductive barrier pattern of the gate contact CB may include a metal or a metal nitride. For example, the conductive barrier pattern may include Ti, Ta, W, TiN, TaN, WN, WCN, TiSiN, TaSiN, WSiN, or a combination thereof, but is not limited thereto.

The upper surface of the upper insulating structure 180 may be covered by a frontside interlayer insulating layer 186. The materials forming the frontside interlayer insulating layer 186 are substantially the same as those of the upper insulating layer 184 described above. A plurality of upper wire layers M1 may be arranged to penetrate the frontside interlayer insulating layer 186. The upper wire layers M1 may be connected to the source/drain via contact VA or the gate contact CB. The upper wire layers M1 may each include Mo, Cu, W, Co, Ru, Mn, Ti, Ta, Al, a combination thereof, or an alloy thereof, but is not limited thereto.

In the manufacturing process of the semiconductor device 100, the first portion BCA1a may be formed in a region where the material for forming the semiconductor block SB is etched, and the second portion BCA2a may be formed a region where the materials for forming the device isolation layer 112 and the backside insulating pattern BBP are etched. In this case, in an existing semiconductor device in which the width of the first portion is the same as that of the second portion, that is, the existing semiconductor device having a rectangular shape in a plan view, the etching selectivity difference between the material for forming the semiconductor block and the materials for forming the device isolation layer and the backside insulating pattern may cause the space for the second portion to be insufficiently formed; thus, problems such as an open failure of backside via contacts formed after the etching process may occur.

In contrast, the semiconductor device 100 according to embodiments of the disclosed concepts may include the backside via contact BCA that includes the first portion BCA1a having a relatively narrow first horizontal width W1 and contacting the semiconductor block SB and the second portion BCA2a having a relatively great second horizontal width W2 and contacting the device isolation layer 112 and the backside insulating pattern BBP. Because the second portion BCA2a has a relatively greater horizontal width than the first portion BCA1a, an open failure of the backside via contact BCA may be prevented, and thus, the functional reliability of the semiconductor device 100 may be improved.

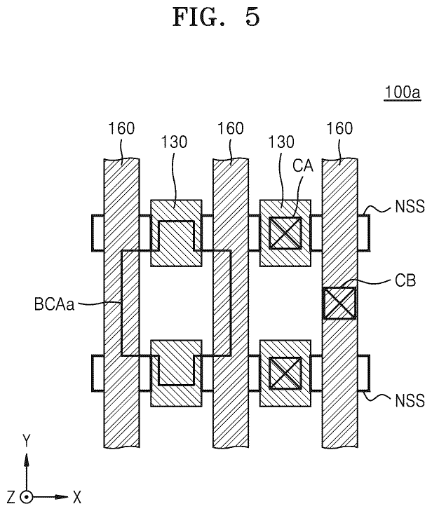

FIG. 5 is a plan layout diagram of a semiconductor device 100a according to embodiments. Because the respective components of the semiconductor device 100a of FIG. 5 are similar to those of the semiconductor device 100 described above with reference to FIGS. 2 to 4D, the differences therebetween are mainly described below.

Referring to FIG. 5, the semiconductor device 100a may be substantially the same as the semiconductor device 100 shown in FIGS. 2 to 4D except that the semiconductor device 100a includes a backside via contact BCAa including a second portion having a square shapes with angled corners.

However, one or more embodiments are not limited thereto. The second portion of the backside via contact BCAa may have a polygonal shape with angled corners, for example, a hexagon, in a plan view.

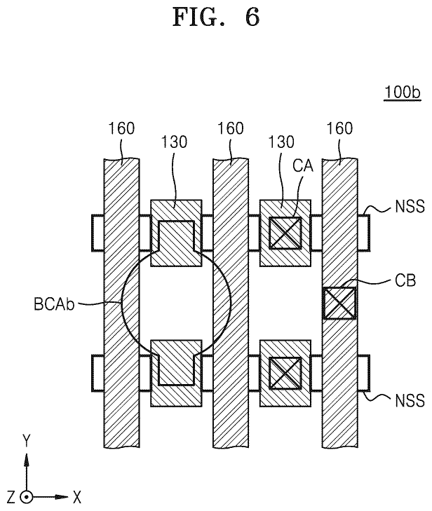

FIG. 6 is a plan layout diagram of a semiconductor device 100b according to embodiments. Because the respective components of the semiconductor device 100b of FIG. 6 are similar to those of the semiconductor device 100 described above with reference to FIGS. 2 to 4D, the differences therebetween are mainly described below.

Referring to FIG. 6, the semiconductor device 100b may be substantially the same as the semiconductor device 100 shown in FIGS. 2 to 4D except that the semiconductor device 100b includes a backside via contact BCAb including a second portion having a convex shape. The second portion of the backside via contact BCAb may be convex outward as the second portion becomes farther from each of the pair of first portions of the backside via contact BCAb in the second horizontal direction (Y direction).

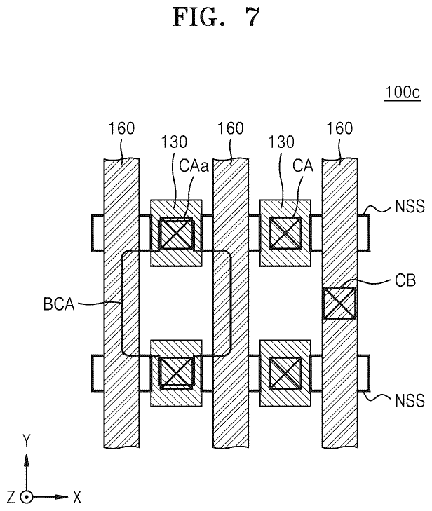

FIG. 7 is a plan layout diagram of a semiconductor device 100c according to embodiments. Because the respective components of the semiconductor device 100c of FIG. 7 are similar to those of the semiconductor device 100 described above with reference to FIGS. 2 to 4D, the differences therebetween are mainly described below.

Referring to FIG. 7, the semiconductor device 100c may be substantially the same as the semiconductor device 100 shown in FIGS. 2 to 4D except that the semiconductor device 100c includes a second frontside contact CAa arranged on the first portion BCA1a of the backside via contact BCA.

The semiconductor device 100c may include a first frontside contact CA, which is arranged on some source/drain regions 130 that do not face the backside via contact BCA among the source/drain regions 130, and a second frontside contact CAa arranged on other source/drain regions 130 that face the backside via contact BCA among the source/drain regions 130. The second frontside contact CAa may have a structure that is substantially the same as or similar to that of the frontside contact CA of the semiconductor device 100 shown in FIGS. 2 to 4D and may include materials that are substantially the same as or similar to those of the frontside contact CA of the semiconductor device 100 shown in FIGS. 2 to 4D. The second frontside contact CAa may face the upper surface of another portion of the source/drain region 130 that faces the backside via contact BCA with the frontside metal silicide layer 172 therebetween.

In embodiments, the second frontside contact CAa may be arranged on each of the pair of first portions of the backside via contacts BCA that face one another in the second horizontal direction (Y direction) with the second portion therebetween. In other words, two second frontside contacts CAa may be arranged on a single backside via contact BCA.

In embodiments, the second frontside contact CAa may be arranged on any one of the pair of first portions of the backside via contact BCA that face one another in the second horizontal direction (Y direction) with the second portion therebetween, while the second frontside contact CAa may not be arranged on the other of the pair of first portions of the backside via contact BCA. In other words, a single second frontside contact CAa may be arranged on a single backside via contact BCA.

In embodiments, the second frontside contact CAa, other source/drain regions 130 facing the backside via contact BCA, and the first portion of the backside via contact BCA may be aligned in the vertical direction (Z direction).

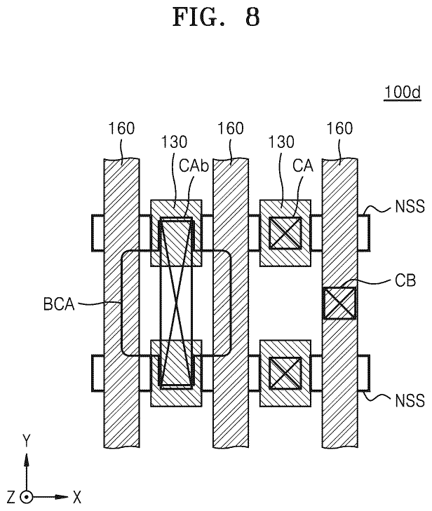

FIG. 8 is a plan layout diagram of a semiconductor device 100d according to embodiments. Referring to FIG. 8, the semiconductor device 100d may be substantially the same as the semiconductor device 100 shown in FIGS. 2 to 4D except that the semiconductor device 100d includes a second frontside contact CAb arranged on the backside via contact BCA.

Referring to FIG. 8, the semiconductor device 100d may include a first frontside contact CA arranged on some of the source/drain regions 130 that do not face the backside via contact BCA, and the second frontside contact CAb arranged on others source/drain regions 130 that face the backside via contact BCA. The second frontside contact CAb may have a structure that is substantially the same as or similar to that of the frontside contact CA of the semiconductor device 100 shown in FIGS. 2A to 4 and may include materials that are substantially the same as or similar to those of the frontside contact CA of the semiconductor device 100 shown in FIGS. 2A to 4.

The second frontside contact CAb may be connected to the upper surface of each of a pair of source/drain regions 130 that face a single backside via contact BCA among the source/drain region 130. In other words, the second frontside contact CAb may be a contact that is commonly connected to the pair of source/drain regions 130. The second frontside contact CAb may be aligned with the first portion and the second portion of the backside via contact BCA in the vertical direction (Z direction). That is, compared to the second frontside contact CAa of the semiconductor device 100c of FIG. 7, the second frontside contact CAb of the semiconductor device 100d of FIG. 8 may extend relatively longer in the second horizontal direction (Y direction).

In embodiments, in a plan view, the second frontside contact CAb may have a rectangular shape extending in the second horizontal direction (Y direction).

In embodiments, the second frontside contact CAb, the other source/drain regions 130 facing the backside via contact BCA, and the backside via contact BCA may be aligned in the vertical direction (Z direction).

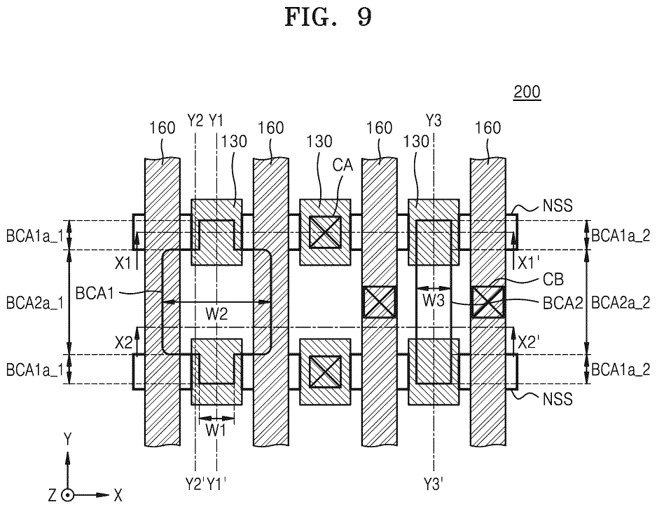

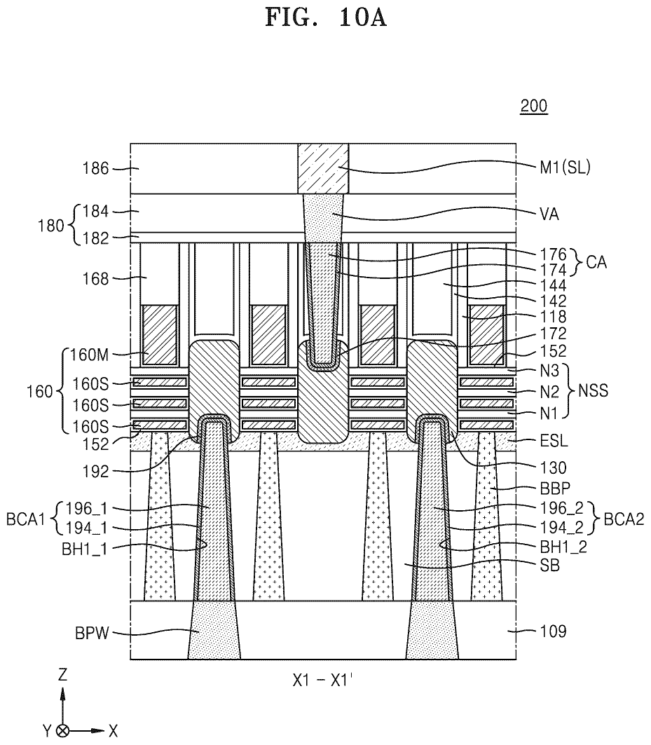

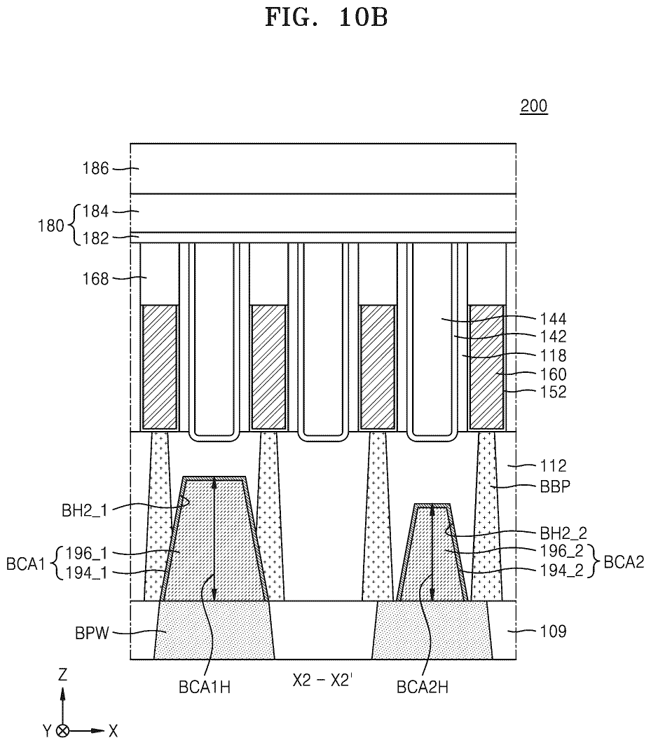

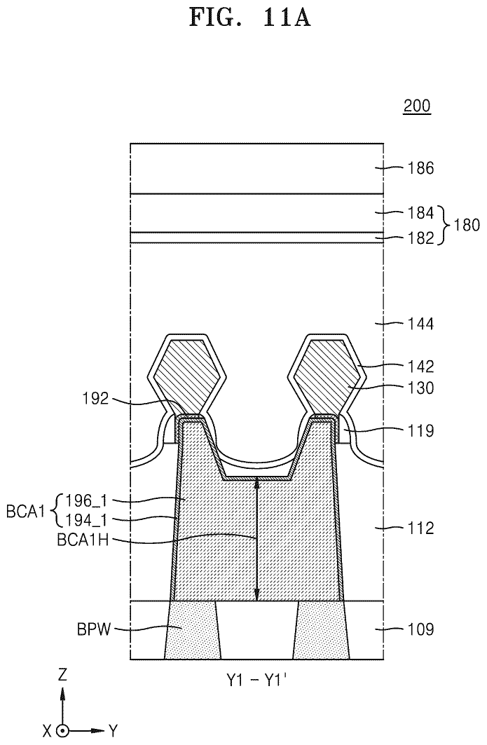

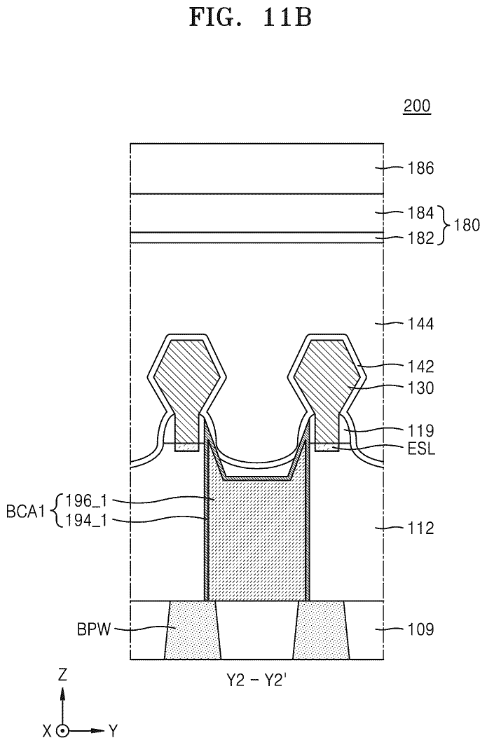

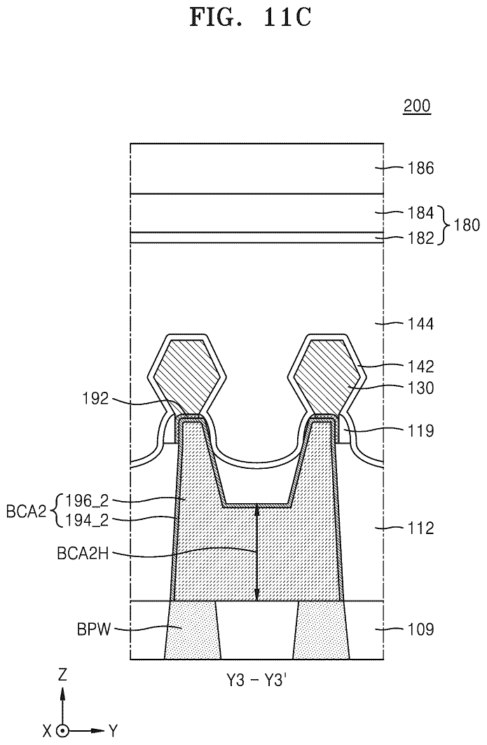

FIG. 9 is a plan layout diagram of a semiconductor device 200 according to embodiments. FIG. 10A is a cross-sectional view taken along a line X1-X1′ of FIG. 9, and FIG. 10B is a cross-sectional view taken along a line X2-X2′ of FIG. 9. FIG. 11A is a cross-sectional view taken along a line Y1-Y1′ of FIG. 9, FIG. 11B is a cross-sectional view taken along a line Y2-Y2′ of FIG. 9, and FIG. 11C is a cross-sectional view taken along a line Y3-Y3′ of FIG. 9. Because the respective components of the semiconductor device 200 of FIGS. 9 to 11C are similar to those of the semiconductor device 100 described above with reference to FIGS. 2 to 4D, the differences therebetween are mainly described below.

Referring to FIGS. 9 to 11C, the semiconductor device 200 may have a structure that is substantially the same as or similar to that of the semiconductor device 100 described with reference to FIGS. 2 to 4D except that the semiconductor device 200 includes a first backside via contact BCA1 and a second backside via contact BCA2 which have different planar shapes.

The semiconductor device 200 may include a first backside via contact BCA1 and a second backside via contact BCA2, wherein the first backside via contact BCA1 is connected to any one pair of source/drain regions 130 spaced apart from one another in the second horizontal direction (Y direction), and the second backside via contact BCA2 is spaced apart from the aforementioned pair of source/drain regions 130 in the first horizontal direction (X direction) and is connected to another pair of source/drain regions 130 spaced apart from one another in the second horizontal direction (Y direction).

The first backside via contact BCA1 may include a second portion BCA2a_1 arranged between any one pair of source/drain regions 130 spaced apart from one another in the second horizontal direction (Y direction), and a pair of first portions BCA1a_1 that respectively face the lower surfaces of the aforementioned pair of source/drain regions 130 and face one another in the second horizontal direction (Y direction) with the second portion BCA2a_1 therebetween.

The pair of first portions BCA1a_1 may respectively face the lower surfaces of a pair of source/drain regions 130 that are commonly connected to a single first backside via contact BCA1. The pair of first portions BCA1a_1 may be in contact with the side surfaces of the semiconductor block SB in the first horizontal direction (X direction), and the second portion BCA2a_1 may be in contact with the device isolation layer 112 and the backside insulating pattern BBP in the first horizontal direction (X direction).

The first portion BCA1a_1 of the first backside via contact BCA1 may have a square shape in a plan view, and the second portion BCA2a_1 of the first backside via contact BCA1 may have a square shape with rounded corners in a plan view. However, one or more embodiments are not limited thereto, and the second portion BCA2a_1 of the first backside via contact BCA1 may have, for example, an angled square shape or a convex shape.

The first portion BCA1a_1 of the first backside via contact BCA1 may have a first horizontal width W1, and the second portion BCA2a_1 may have a second horizontal width W2. In embodiments, the first horizontal width W1 may be less than the second width W2.

The second backside via contact BCA2 may be spaced apart from the first backside via contact BCA1 in the first horizontal direction (X direction). The second backside via contact BCA2 may include a second portion BCA2a_2 and a pair of first portions BCA1a_2, wherein the second portion BCA2a_2 corresponds to the second portion BCA2a_1 of the first backside via contact BCA1 in the first horizontal direction (X direction), and the first portions BCA1a_2 correspond to a pair of first portions BCA1a_1 of the first backside via contact BCA1 in the first horizontal direction (X direction). In a plan view, the second backside via contact BCA2 may have a rectangular shape. In other words, the second portion BCA2a_2 and the pair of first portions BCA1a_2 of the second backside via contact BCA2 may have the same third horizontal width W3. In embodiments, the third horizontal width W3 may be substantially the same as the first horizontal width W1.

The pair of first portions BCA1a_2 may respectively face the lower surfaces of a pair of source/drain regions 130 that are commonly connected to a single second backside via contact BCA2. The pair of first portions BCA1a_2 may be in contact with the side surfaces of the semiconductor block SB in the first horizontal direction (X direction), and the second portion BCA2a_2 may be in contact with the device isolation layer 112 in the first horizontal direction (X direction). In other words, unlike the second portion BCA2a_1 of the first backside via contact BCA1, the second portion BCA2a_2 of the second backside via contact BCA2 may be spaced apart from the backside insulating pattern BBP in the first horizontal direction (X direction).

A vertical height BCA2H of the second portion BCA2a_2 of the second backside via contact BCA2 may be less than a vertical height BCA1H of the second portion BCA2a_1 of the first backside via contact BCA1. Such a vertical height difference may be caused as a hole for the second portion BCA2a_1 of the first backside via contact BCA1 may be etched further than a hole for the second portion BCA2a_2 of the second backside via contact BCA2 in the manufacturing process of the semiconductor device 200 when the respective holes for the second portion BCA2a_1 of the first backside via contact BCA1 and the second portion BCA2a_2 of the second backside via contact BCA2 are etched, because the second horizontal width W2 of the second portion BCA2a_1 of the first backside via contact BCA1 is greater than the third horizontal width W3 of the second portion BCA2a_2 of the second backside via contact BCA2.

The upper surface of the first portion BCA1a_1 of the first backside via contact BCA1 may be at the same vertical level as the upper surface of the first portion BCA1a_2 of the second backside via contact BCA2.

The upper surface of the second portion BCA2a_1 of the first backside via contact BCA1 may be at a higher vertical level than the upper surface of the second portion BCA2a_2 of the second backside via contact BCA2.

The first backside via contact BCA1 may include a first conductive barrier pattern 194_1 and a first contact plug 196_1, and the second backside via contact BCA2 may include a second conductive barrier pattern 194_2 and a second contact plug 196_2. The first conductive barrier pattern 194_1 and the first contact plug 196_1 of the first backside via contact BCA1 and the second conductive barrier pattern 194_2 and the second contact plug 196_2 of the second backside via contact BCA2 may be substantially the same as or similar to the conductive barrier pattern 194 and the contact plug 196 of the semiconductor device 100 shown in FIGS. 2 to 4D, respectively.

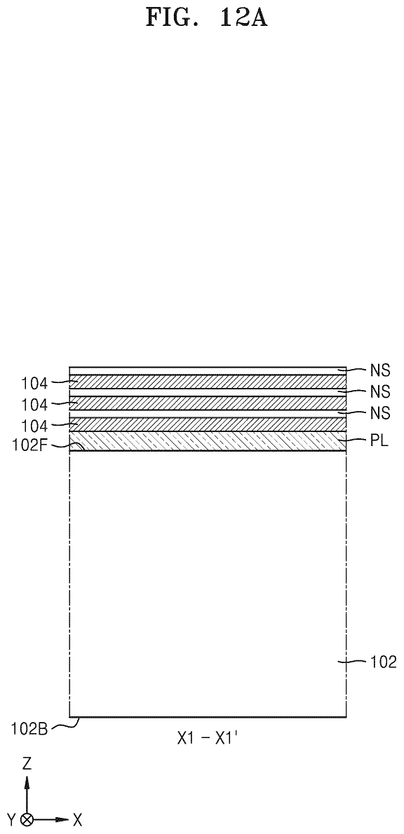

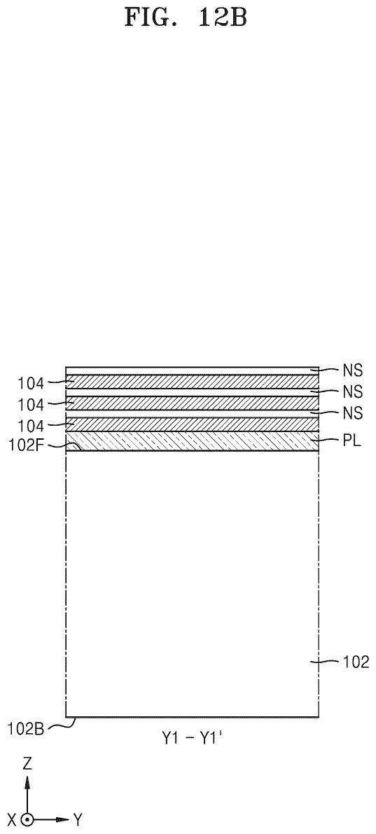

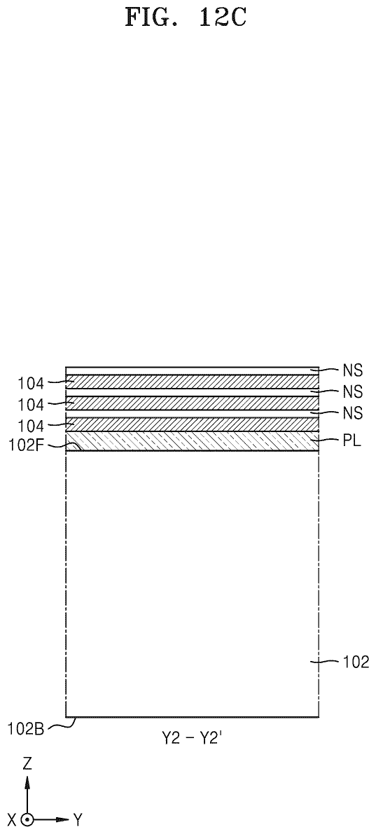

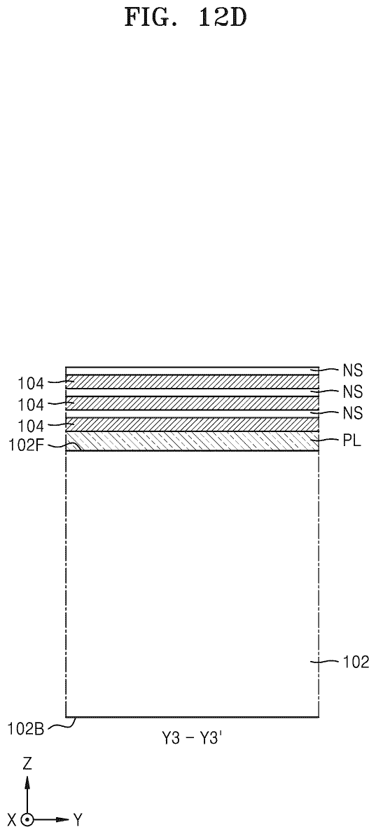

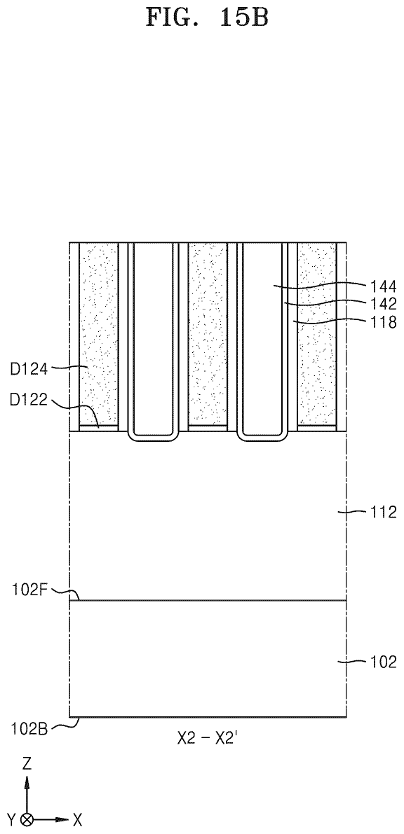

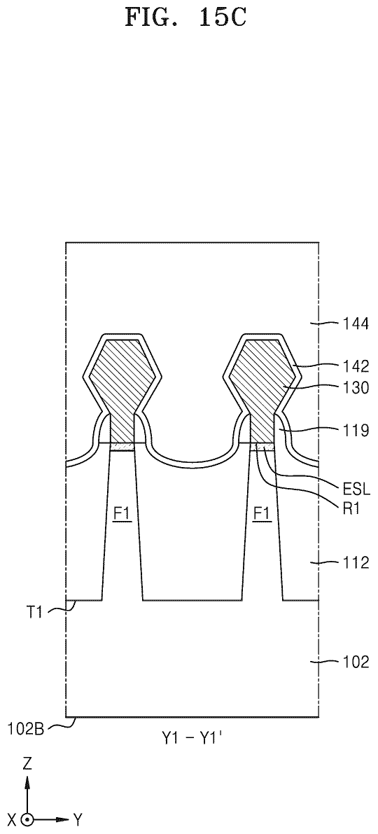

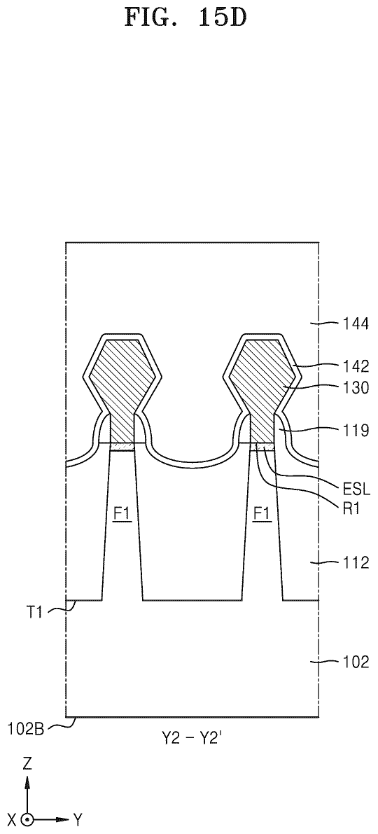

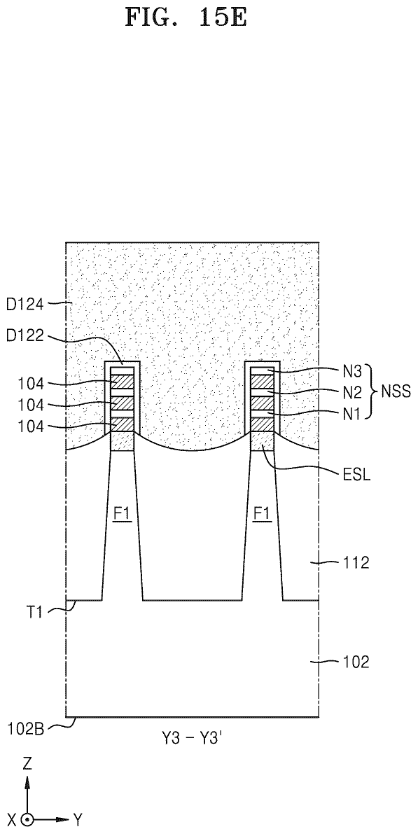

FIGS. 12A to 21E are cross-sectional views for explaining respective operations of a method of manufacturing a semiconductor device, according to embodiments. In detail, FIGS. 12A to 21A are cross-sectional views taken along a line X1-X1′ of FIG. 2, FIGS. 15B to 21B are cross-sectional views taken along a line X2-X2′ of FIG. 2, FIGS. 12B to 14B and 15C to 21C are cross-sectional views taken along a line Y1-Y1′ of FIG. 2, FIGS. 12C to 14C and 15D to 21D are cross-sectional views taken along a line Y2-Y2′ of FIG. 2, and FIGS. 12D to 14D and FIGS. 15E to 21E are cross-sectional views taken along a line Y3-Y3′ of FIG. 2.

Referring to FIGS. 12A to 12D, a substrate 102 including a frontside surface 102F and a backside surface 102B that face one another may be prepared first, a sacrificial layer PL may be formed on the frontside surface 102F of the substrate 102, and a stack structure, in which the sacrificial semiconductor layers 104 and the nanosheet semiconductor layers NS are alternately stacked layer by layer, may be formed on the sacrificial layer PL.

In the above stack structure, the sacrificial semiconductor layers 104 and the nanosheet semiconductor layers NS may include different semiconductor materials with different etch selectivity. In embodiments, each nanosheet semiconductor layer NS may include an Si layer, while each sacrificial semiconductor layer 104 may include an SiGe layer. The SiGe layer forming the sacrificial semiconductor layer 104 may have a constant Ge content selected in a range from about 5 atomic percent (at %) to about 50 at %, for example, from about 10 at % to about 40 at %. In embodiments, the sacrificial semiconductor layers 104 may each include an SiGe layer, and the Ge content of each sacrificial semiconductor layer 104 may be the same.

The sacrificial layer PL may include an SiGe layer in a similar manner to the sacrificial semiconductor layers 104. However, the Ge content of the SiGe layer forming the sacrificial layer PL may be greater than that of the SiGe layers forming the sacrificial semiconductor layers 104. In embodiments, the sacrificial layer PL may have a Ge content selected in a range from about 60 at % to about 70 at %. For example, the sacrificial layer PL may have the Ge content of about 65 at %.

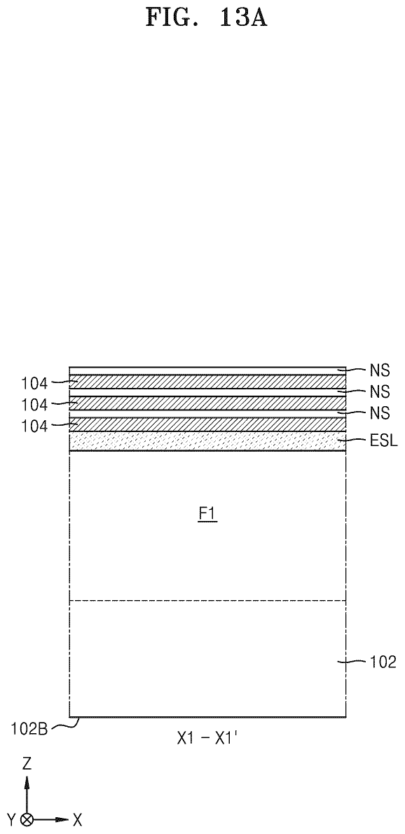

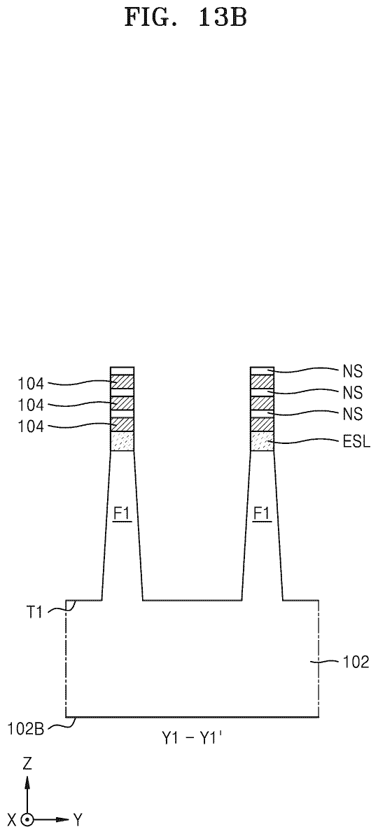

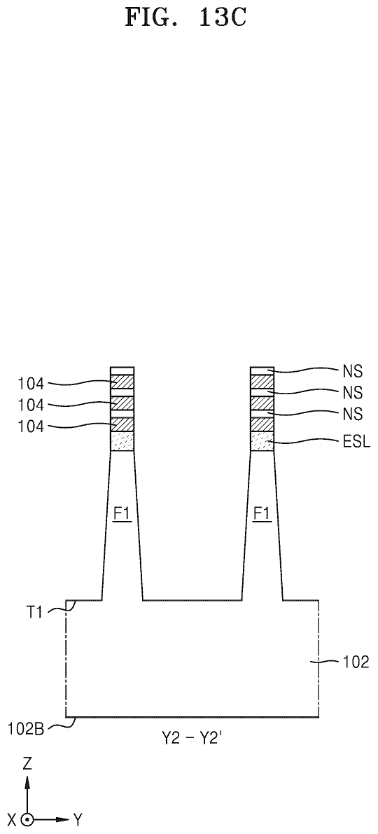

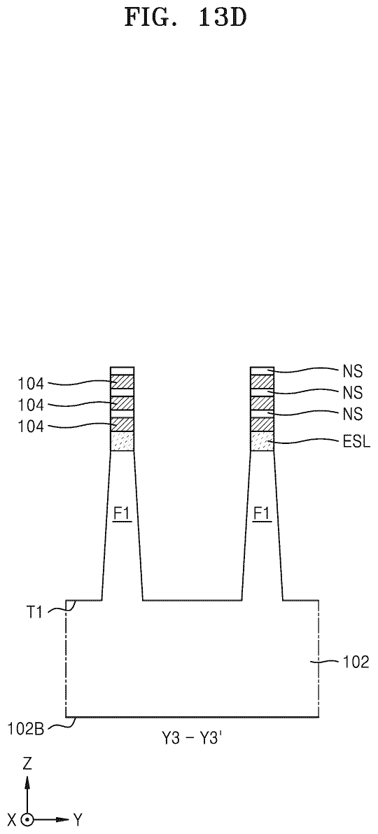

Referring to FIGS. 13A to 13D, by etching a portion of each of the sacrificial semiconductor layers 104, the nanosheet semiconductor layers NS, the sacrificial layer PL, and the substrate 102 from the result of FIGS. 12A to 12D, a plurality of fin-type active regions F1 defining a trench region T1 may be formed in the substrate 102. The stack structure including the sacrificial layer PL, the sacrificial semiconductor layers 104, and the nanosheet semiconductor layers NS may remain on the upper surface of each fin-type active region F1.

Then, the sacrificial layer PL exposed on the sidewalls of the stack structure may be replaced with an etch stop layer ESL. In embodiments, to replace the sacrificial layer PL with the etch stop layer ESL, the sacrificial layer PL may first be selectively removed from the sidewalls of the stack structure, and then, the space where the sacrificial layer PL was located may be filled with the etch stop layer ESL. To selectively remove the sacrificial layer PL, a selective wet etching process utilizing the Ge content difference may be performed.

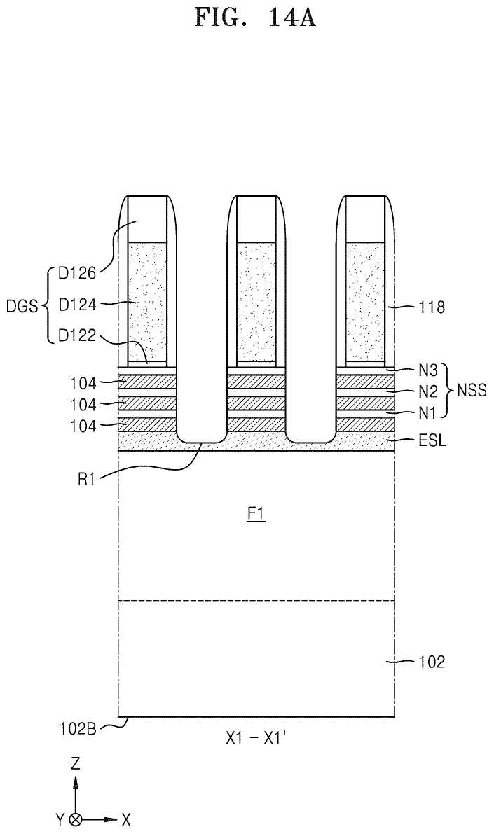

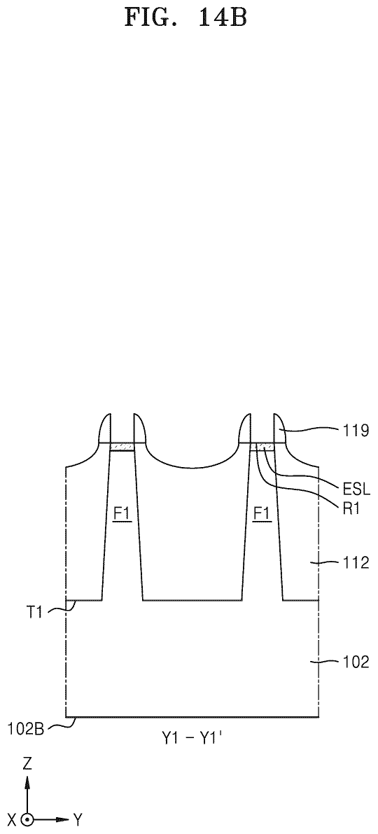

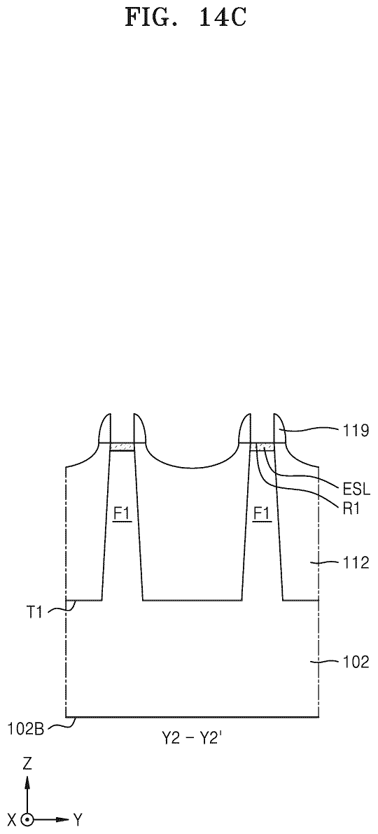

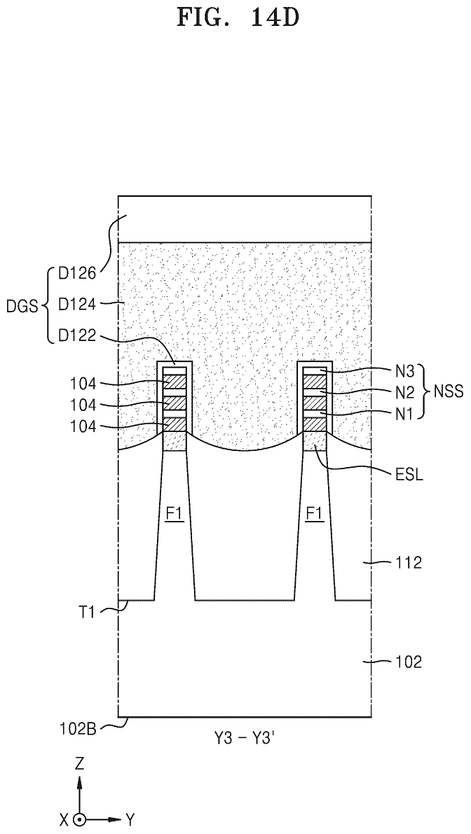

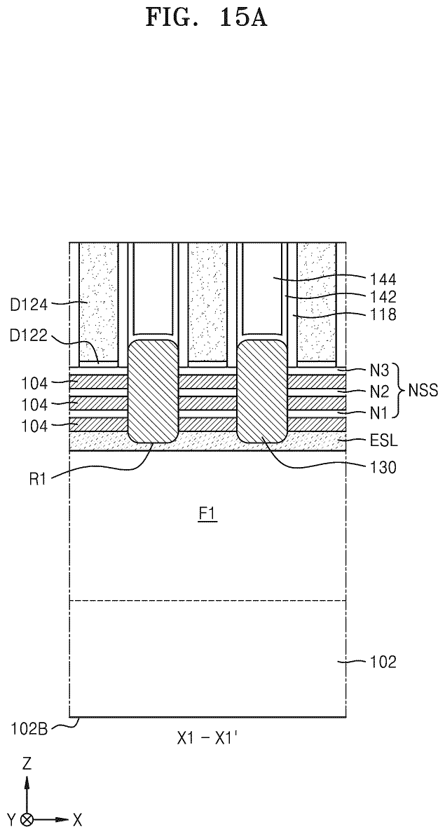

Referring to FIGS. 14A to 14D, the device isolation layer 112 filling the trench region T1 may be formed on the result of FIGS. 13A to 13D. After the formation of the device isolation layer 112, the sidewalls of each fin-type active region F1 and the sidewalls of the etch stop layer ESL may be covered by the device isolation layer 112.

Then, a plurality of dummy gate structures DGS may be formed on the stack structure including the etch stop layer ESL, the sacrificial semiconductor layers 104, and the nanosheet semiconductor layers NS. Each dummy gate structure DGS may be formed to extend in the second horizontal direction (Y direction). Each dummy gate structure DGS may have a structure in which an oxide layer D122, a dummy gate layer D124, and a capping layer D126 are sequentially stacked. In embodiments, the dummy gate layer D124 may include polysilicon, and the capping layer D126 may include a silicon nitride layer.

After the formation of a plurality of main insulating spacer 118 covering both sidewalls of each dummy gate structure DGS, a portion of each of the sacrificial semiconductor layers 104 and the nanosheet semiconductor layers NS may be etched by using the dummy gate structures DGS and the main insulating spacer 118 as etch masks, and the nanosheet semiconductor layers NS may be divided into a plurality of nanosheet stacks NSS; thus, a plurality of recesses R1 may be formed over the etch stop layer ESL. Each nanosheet stack NSS may include a first nanosheet N1, a second nanosheet N2, and a third nanosheet N3. Dry etching, wet etching, or a combination thereof may be performed to form the recesses R1. After the recesses R1 are formed, a plurality of side insulating spacers 119 may be formed on the device isolation layer 112 to be adjacent to the recesses R1 on both sides of each fin-type active region F1.

Referring to FIGS. 15A to 15E, the source/drain regions 130 filling the recesses R1 may be formed on the results of FIGS. 14A to 14D. To form the source/drain regions 130, semiconductor materials may be epitaxially grown from the sidewalls of each of the first nanosheet N1, the second nanosheet N2, and the third nanosheet N3 included in the nanosheet stack NSS exposed within the recesses R1.

Then, an insulating liner 142 covering the result, on which the source/drain regions 130 are formed, may be formed, an inter-gate insulating layer 144 may be formed on the insulating liner 142, and then, the upper surfaces of the capping layers D126 may be exposed by etching a portion of each of the insulating liner 142 and the inter-gate insulating layer 144. Then, the capping layers D126 may be removed to expose the dummy gate layer D124, and portions of the insulating liner 142 and the inter-gate insulating layer 144 may be removed so that the upper surface of the inter-gate insulating layer 144 is at substantially the same level as the upper surface of the dummy gate layer D124.

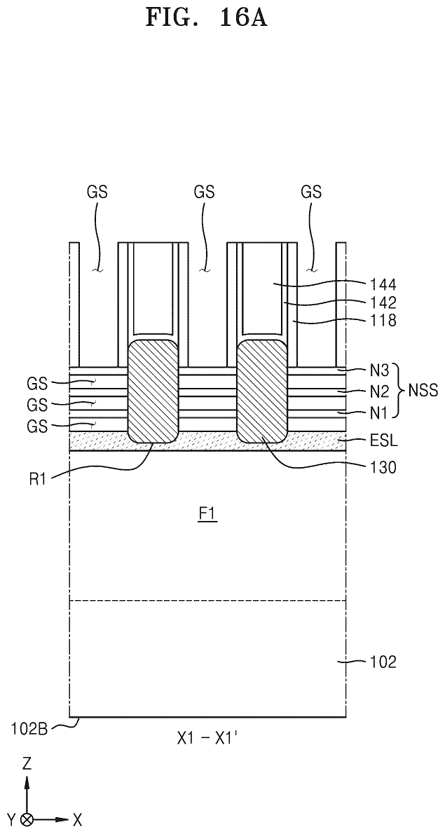

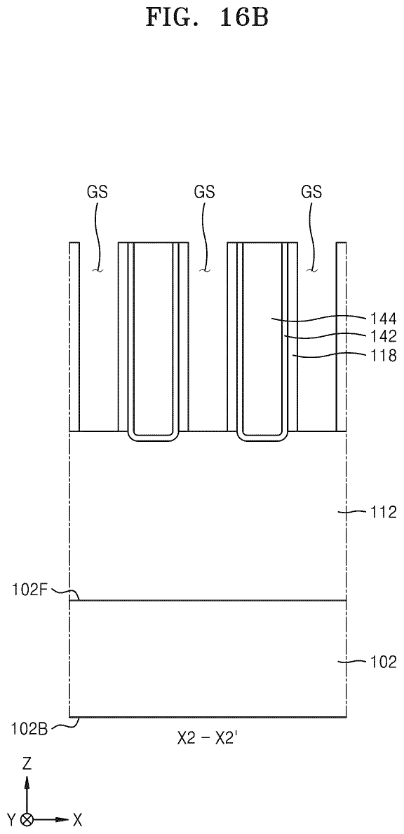

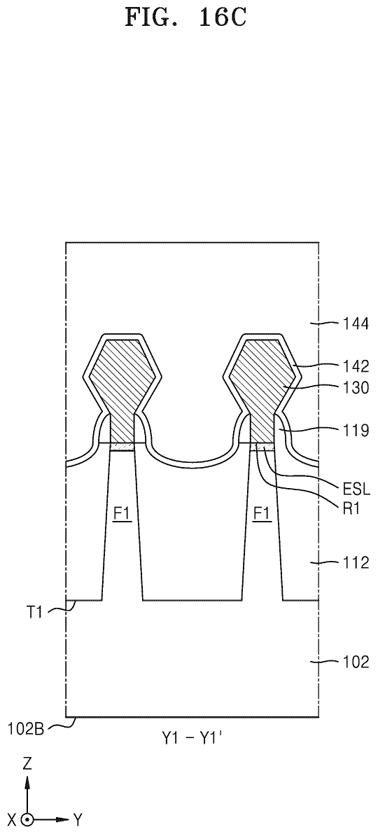

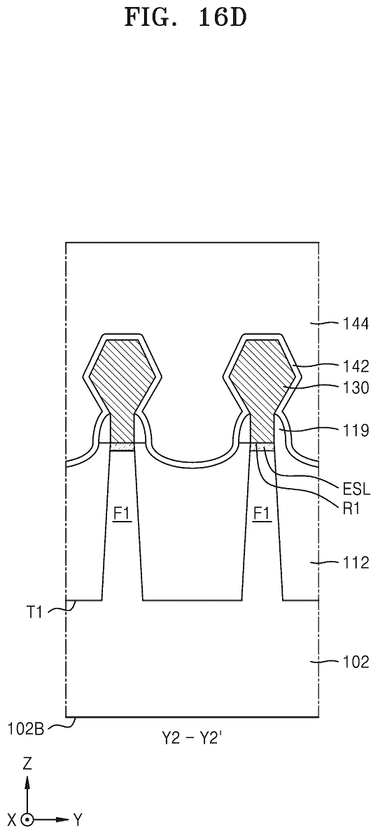

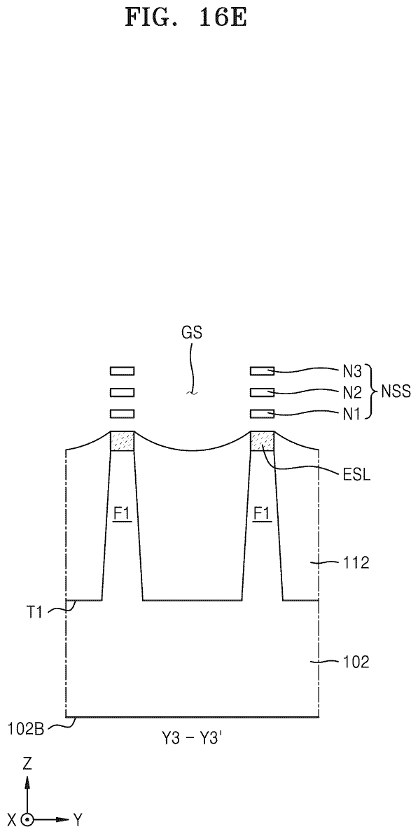

Referring to FIGS. 16A to 16E, on the result of FIGS. 15A to 15E, a gate space GS may be prepared by removing the dummy gate layer D124 and the oxide layer D122 thereunder, and the nanosheet stacks NSS may be exposed through the gate space GS. Then, portions of the sacrificial semiconductor layers 104 remaining on the fin-type active region F1 may be removed through the gate space GS so that the gate space GS may extend to the spaces between the first nanosheet N1, the second nanosheet N2, and the third nanosheet N3 and the space between the first nanosheet N1 and the etch stop layer ESL. In embodiments, the difference in the etch selectivity between the first nanosheet N1 to the third nanosheet N3 and the sacrificial semiconductor layers 104 may be used to selectively remove the sacrificial semiconductor layers 104.

A liquid or gaseous etchant may be used to selectively remove the sacrificial semiconductor layers 104. In embodiments, a CH₃COOH-based etchant, for example, an etchant containing a mixture of CH₃COOH, HNO₃, and HF or an etchant containing a mixture of CH₃COOH, H₂O₂, and HF may be used to selectively remove the sacrificial semiconductor layers 104, but one or more embodiments are not limited thereto.

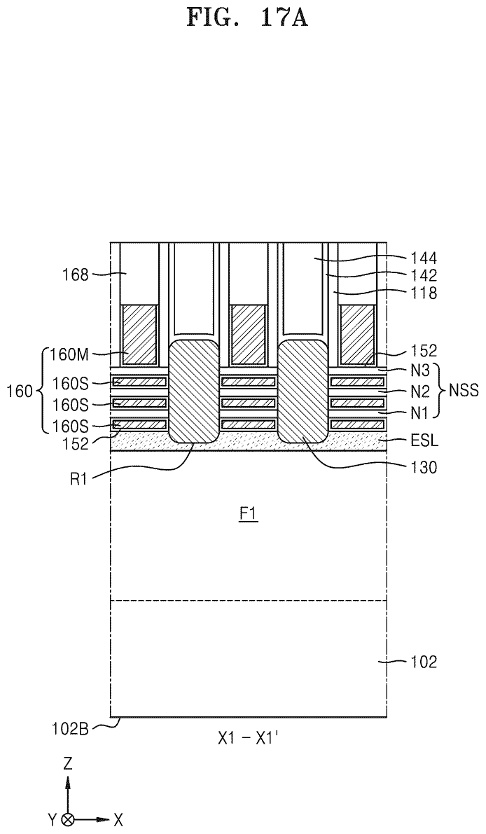

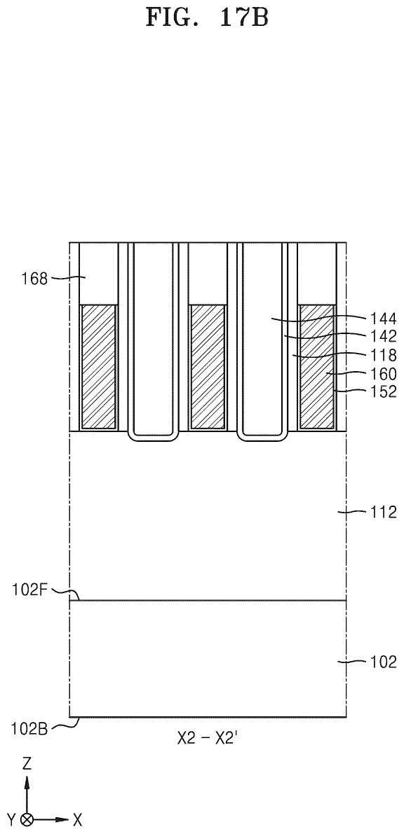

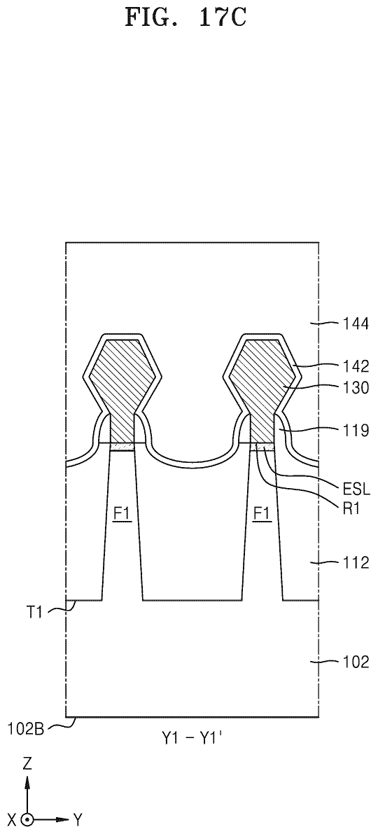

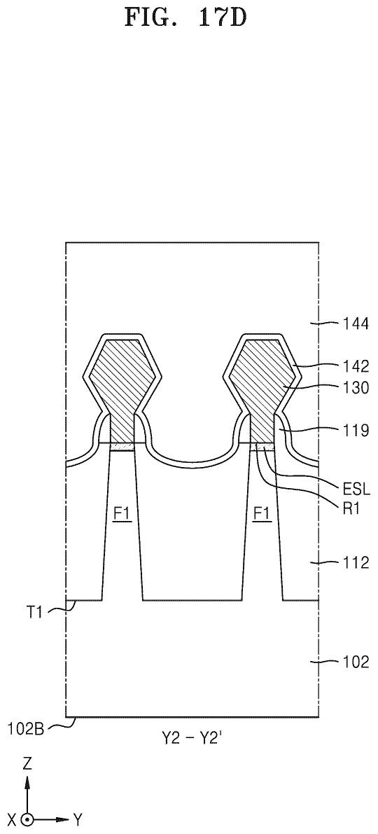

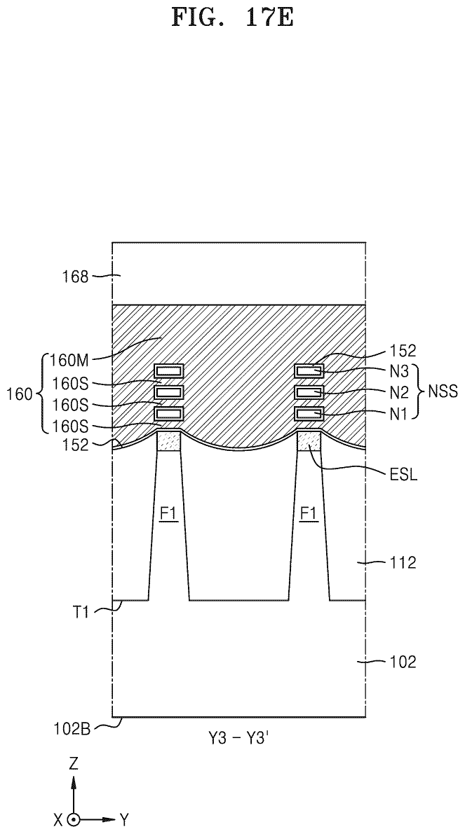

Referring to FIGS. 17A to 17E, on the result of FIGS. 16A to 16E, the gate dielectric layer 152 may be formed to cover the exposed surfaces of the first nanosheet N1, the second nanosheet N2, the third nanosheet N3, the etch stop layer ESL, and the device isolation layer 112. An Atomic Layer Deposition (ALD) process may be performed to form the gate dielectric layer 152.

Then, on the gate dielectric layer 152, the gate line 160 filling a portion of the gate space GS (see FIGS. 16A, 16B, and 16E) and the capping insulating pattern 168 covering the upper surface of each of the gate line 160 and the gate dielectric layer 152 in the gate space GS may be formed.

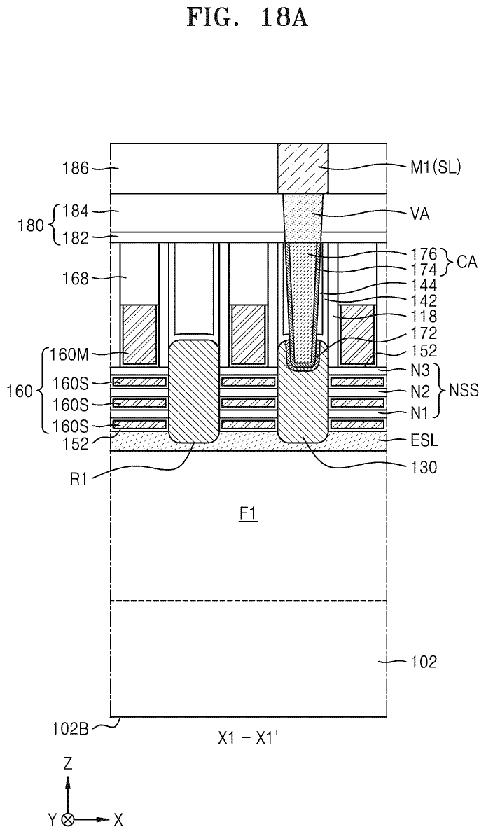

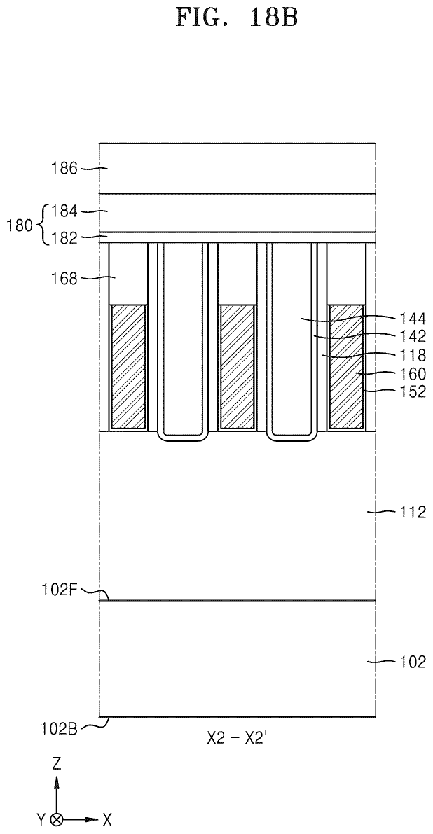

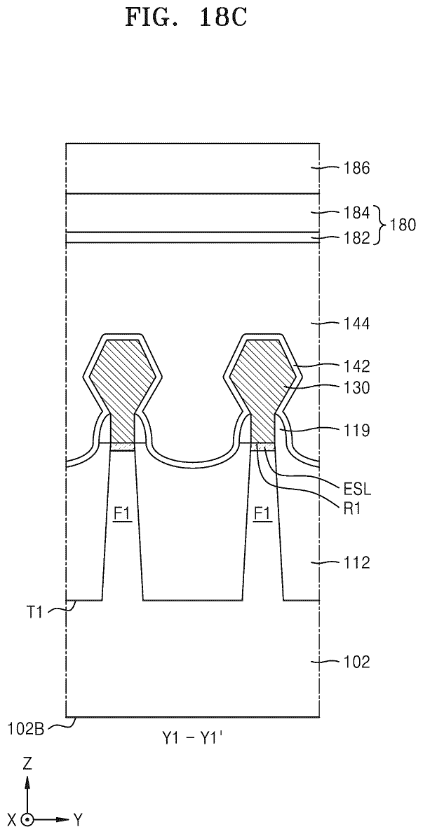

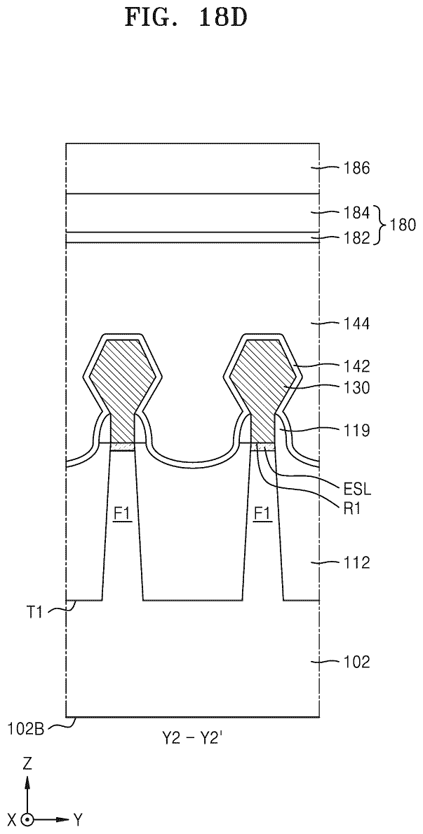

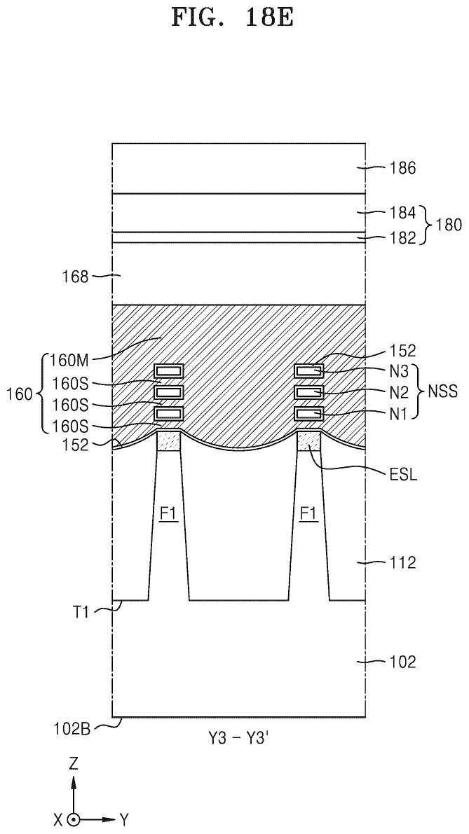

Referring to FIGS. 18A to 18E, on the result of FIGS. 17A to 17E, after the formation of the source/drain contact holes exposing the source/drain regions 130 by penetrating the inter-gate insulating layer 144 and the insulating liner 142, some portions of the source/drain regions 130 may be anisotropically removed through the source/drain contact holes such that the source/drain contact holes may extend further towards the substrate 102. Then, the metal silicide layer 172 may be formed on the source/drain region 130 exposed within each of the source/drain contact holes. In embodiments, to form the metal silicide layer 172, a process may be performed which includes forming a metal liner (not shown) conformally covering the exposed surface of the source/drain region 130 and then thermally treating the metal liner to induce a reaction between the source/drain region 130 and the metal forming the metal liner. After the metal silicide layer 172 is formed, remaining portions of the metal liner may be removed. During the process of forming the metal silicide layer 172, portions of the source/drain regions 130 may be consumed. In embodiments, when the metal silicide layer 172 includes a titanium silicide layer, the metal liner may include a Ti layer.

Then, the frontside source/drain contact CA including the conductive barrier pattern 174 and the contact plug 176 may be formed within each of the source/drain contact holes.

Next, the etch stop layer 182 and the upper insulating layer 184 respectively covering the upper surfaces of the inter-gate insulating layer 144, the frontside source/drain contacts CA, the capping insulating patterns 168 may be sequentially formed, thereby forming the upper insulating structure 180.

Then, the source/drain via contacts VA connected to the frontside source/drain contacts CA by penetrating the upper insulating structure 180 in the vertical direction (Z direction) and the gate contact CB (see FIG. 4C) connected to the gate line 160 by penetrating the upper insulating structure 180 and the capping insulating pattern 168 in the vertical direction (Z direction) may be formed. The source/drain via contact VA and the gate contact CB may be formed either simultaneously or through separate processes. The order in which the source/drain via contact VA and the gate contact CB are formed is not particularly limited.

Then, the interlayer insulating layer 186 covering the upper insulating structure 180 and a plurality of upper wire layers M1 penetrating the interlayer insulating layer 186 may be formed. The upper wire layers M1 may each include an upper wire layer M1 connected to the source/drain via contact VA and an upper wire layer MI connected to the gate contact CB.

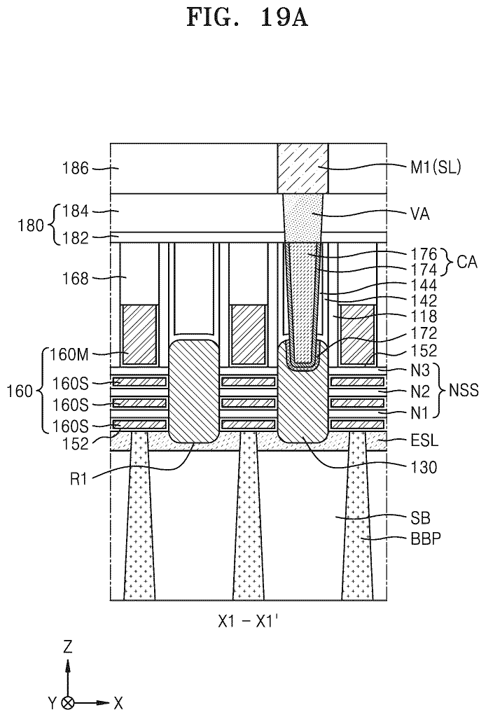

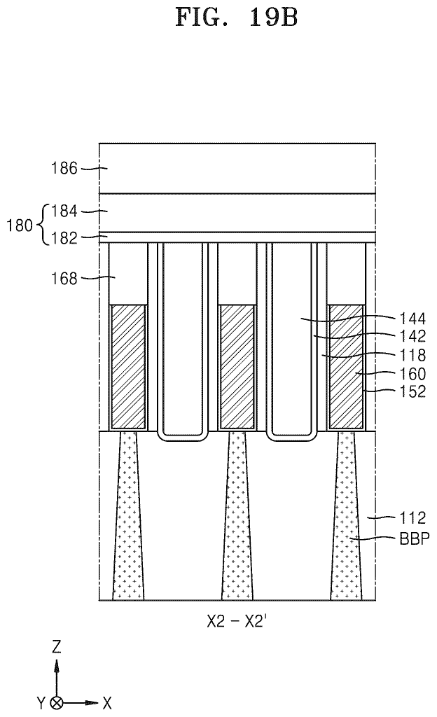

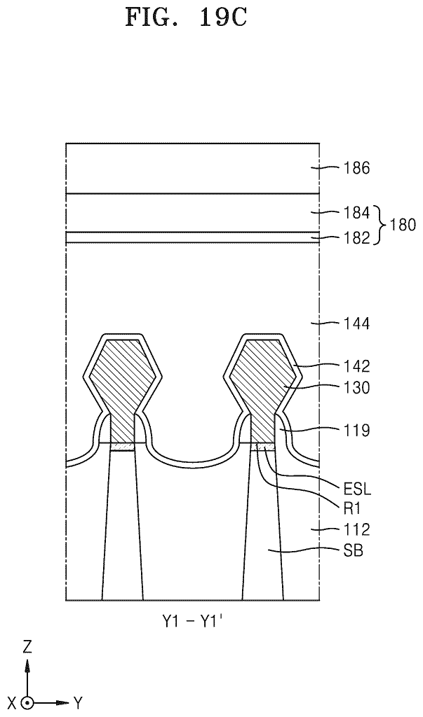

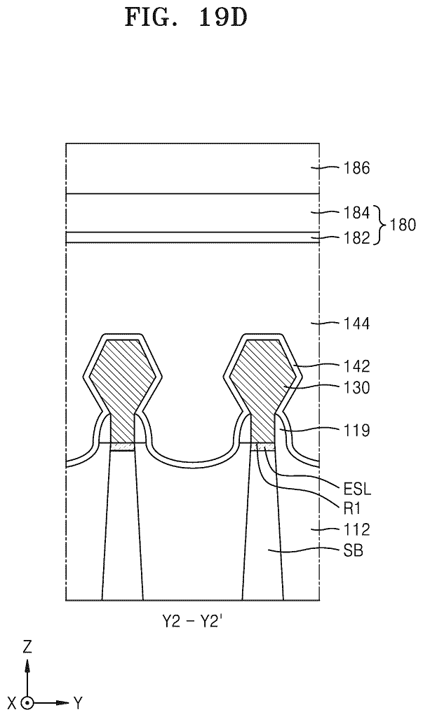

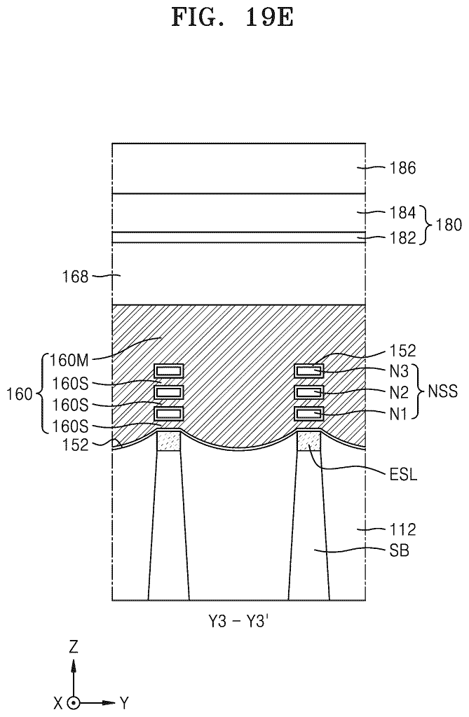

Referring to FIGS. 19A to 19E, on the result of FIGS. 18A to 18E, the fin-type active regions F1 and the device isolation layer 112 may be exposed by removing the substrate 102 from the backside surface 102B of the substrate 102. In embodiments, the process of removing the substrate 102 may include at least one process selected from among a mechanical grinding process, a Chemical Mechanical Polishing (CMP) process, a wet etching process, and a combination thereof.

Then, a plurality of vertical holes exposing the gate dielectric layer 152 may be formed by respectively etching portions of the fin-type active regions F1 from the backside surface on which the fin-type active regions F1 and the device isolation layer 112 are exposed, and a plurality of backside insulating patterns BBP may then be formed to fill the vertical holes. As the backside insulating patterns BBP are formed, each fin-type active region F1 may be divided into a plurality of semiconductor blocks SB that are separated from one another by the backside insulating patterns BBP. In embodiments, an ALD process or a Chemical Vapor Deposition (CVD) process may be performed to form the backside insulating patterns BBP, but one or more embodiments are not limited thereto.

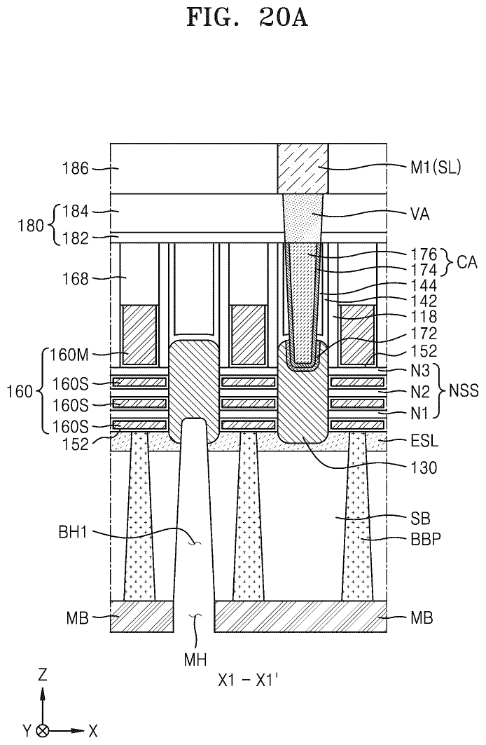

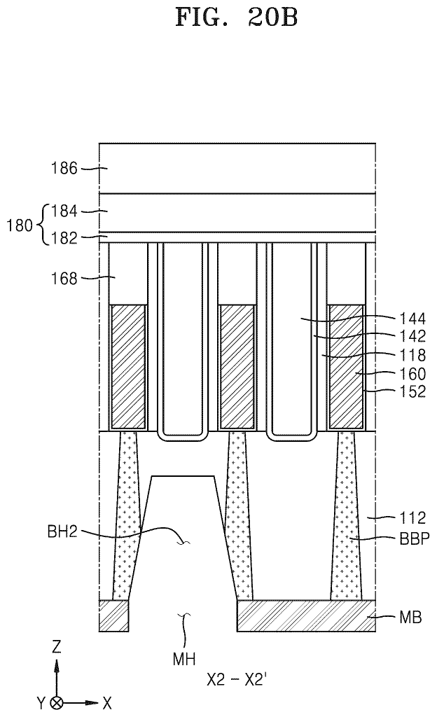

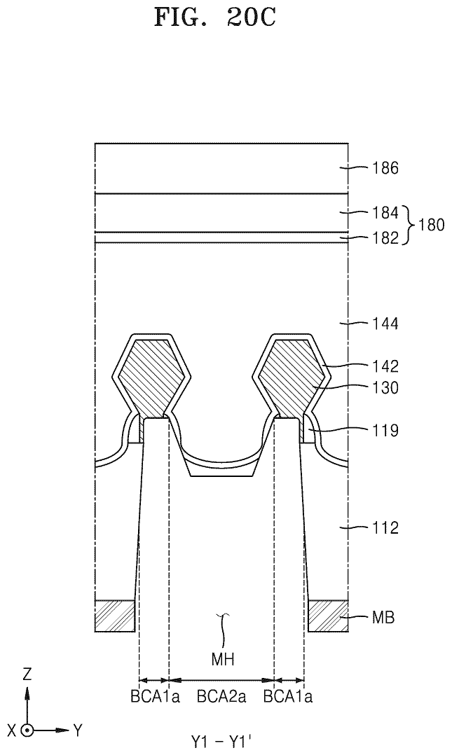

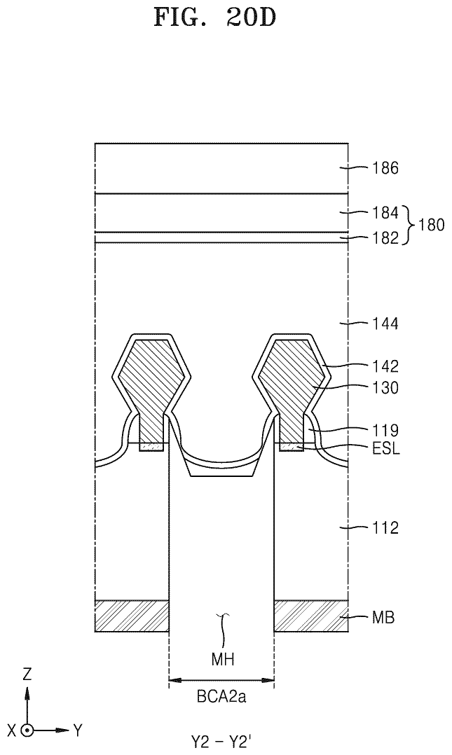

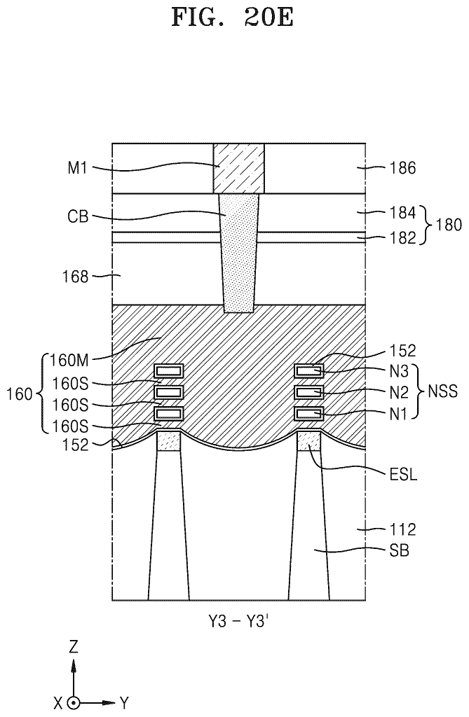

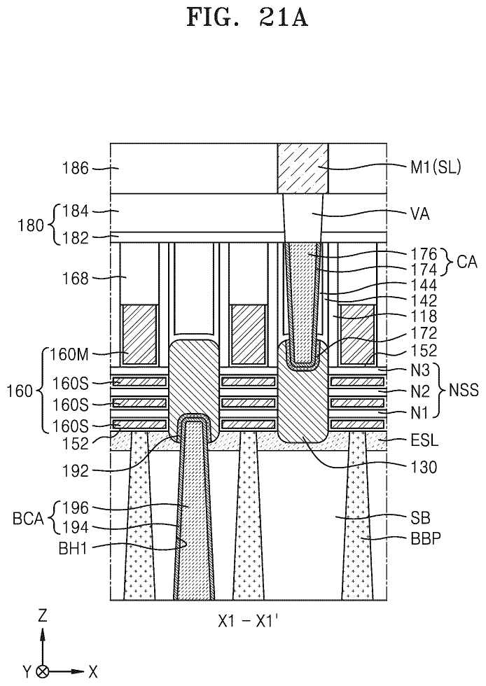

Referring to FIGS. 20A to 20E, on the result of FIGS. 19A to 19E, a hard mask pattern MB may be formed on the lower surface of each of the exposed semiconductor blocks SB, the backside insulating patterns BBP, and the device isolation layer 112. The hard mask pattern MB may include an opening MH exposing a local region of a removal target of each of the backside insulating patterns BBP and the semiconductor blocks SB.

Then, by using the hard mask pattern MB as an etch mask and the etch stop layer ESL as an etch endpoint, a local region of semiconductor block SB exposed through the opening MH may be anisotropically etched to form a first space BH1 exposing the etch stop layer ESL, and a second space BH2 may be formed by anisotropically etching local regions of the backside insulating pattern BBP and the device isolation layer 112. During the etching process, the first space BH1 may be formed relatively deeper than the second space BH2 because of the differences in etch selectivity between the semiconductor blocks SB, the device isolation layer 112, and the backside insulating pattern BBP. The first space BHI may be a region where the first portion BCA1a of the backside via contact BCA of the semiconductor device 100 is formed, and the second space BH2 may be a region where the second portion BCA2a of the backside via contact BCA of the semiconductor device 100 is formed.

The hard mask pattern MB may include a material with etch selectivity with respect to the respective materials for forming the semiconductor block SB, the device isolation layer 112, and the backside insulating pattern BBP. For example, the hard mask pattern MB may include a silicon nitride layer, a carbon-containing layer, or a combination thereof, but is not limited thereto.

Then, the source/drain region 130 may be exposed by etching the etch stop layer ESL exposed through the first space BH1, and some portions of the source/drain region 130 exposed through the first space BH1 may be removed through an anisotropic etching process so that the first space BH1 may extend further into the source/drain region 130.

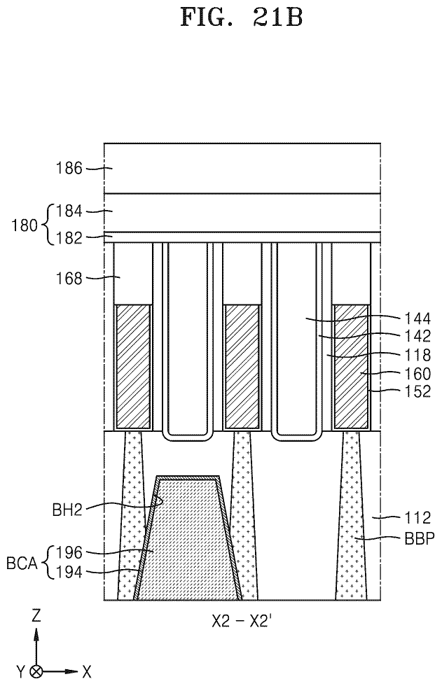

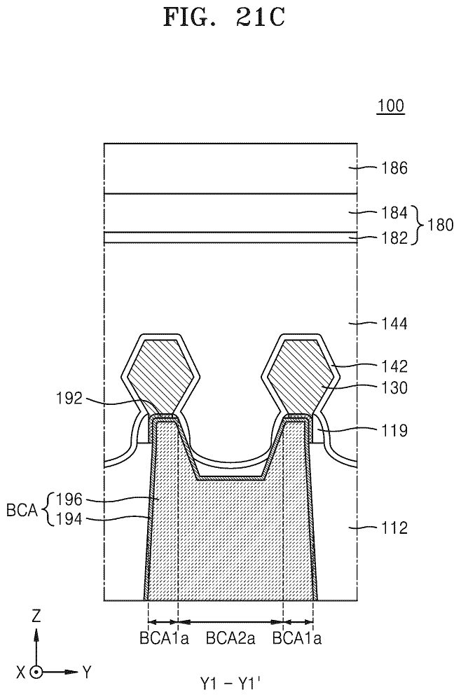

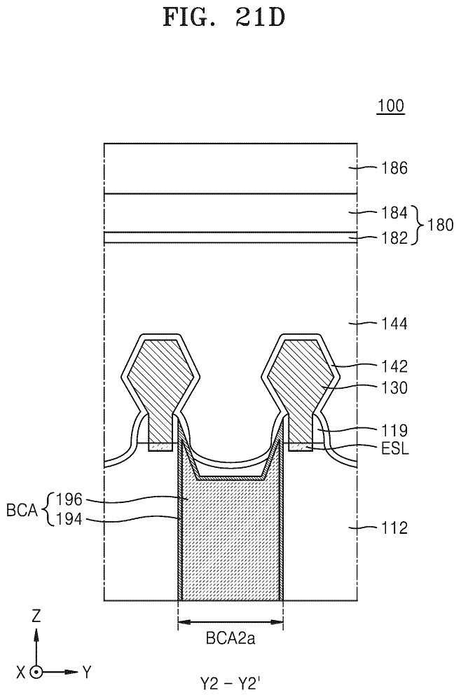

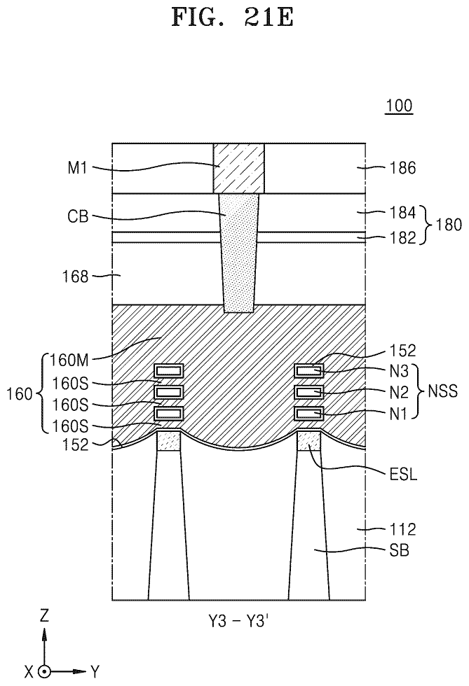

Referring to FIGS. 21A to 21E, on the result of FIGS. 20A to 20E, a process of forming a metal silicide layer 192 on the surface of the source/drain region 130 exposed through the first space BHI as well as a process of forming a backside via contact BCA filling the first space BH1 and the second space BH2 may be performed. The backside via contact BCA may include a conductive barrier pattern 194 and a contact plug 196. To form the metal silicide layer 192 and the backside via contact BCA, processes that are similar to the processes of forming the metal silicide layer 172 and the frontside source/drain contact CA described with reference to FIGS. 18A to 18E may be performed.

Next, on the result of FIGS. 21A to 21E, the backside insulating layer 109 may be formed to cover the lower surface of each of the exposed semiconductor blocks SB, the backside insulating patterns BBP, and the device isolation layer 112, and the backside power rail BPW contacting an end portion of the backside via contact BCA may be formed by penetrating the backside insulating layer 109 in the vertical direction (Z direction); thus, the semiconductor device 100 described with reference to FIGS. 2 to 4D may be manufactured.

While the disclosed concepts have been particularly shown and described with reference to embodiments thereof, it will be understood that various changes in form and details may be made therein without departing from the spirit and scope of the following claims.

What is claimed is:

1. A semiconductor device comprising:
a plurality of gate lines that are neighboring one another in a first horizontal direction and each extend in a second horizontal direction substantially perpendicular to the first horizontal direction;
a plurality of source/drain regions arranged adjacent to the plurality of gate lines in the first horizontal direction, respectively;
a backside via contact connected to a pair of source/drain regions that face one another in the second horizontal direction among the plurality of source/drain regions;
a plurality of backside insulating patterns aligned with the plurality of gate lines in a vertical direction and spaced apart from one another in the first horizontal direction;
a plurality of semiconductor blocks contacting sidewalls of the plurality of backside insulating patterns in the first horizontal direction; and
a device isolation layer covering sidewalls of the backside via contact in the second horizontal direction,
wherein:
the backside via contact comprises a pair of first portions that face the pair of source/drain regions, and a second portion arranged between the pair of first portions, and
a first horizontal width of the pair of first portions in the first horizontal direction is less than a second horizontal width of the second portion in the first horizontal direction.

2. The semiconductor device of claim 1, wherein:
the pair of first portions are in contact with the plurality of semiconductor blocks in the first horizontal direction, and
the second portion is in contact with the device isolation layer and some of the plurality of backside insulating patterns in the first horizontal direction.

3. The semiconductor device of claim 1, wherein the second portion has a polygonal shape with rounded corners in a plan view.

4. The semiconductor device of claim 1, wherein the second portion has a polygonal shape with angled corners in a plan view.

5. The semiconductor device of claim 1, wherein the second portion has a shape that is convex towards the outer side of the second portion as the second portion becomes farther from each of the pair of first portions in the second horizontal direction.

6. The semiconductor device of claim 1, wherein upper surfaces of the pair of first portions are at a higher vertical level than a vertical level of an upper surface of the second portion.

7. The semiconductor device of claim 1, further comprising a frontside contact connected to one selected from among the plurality of source/drain regions, wherein the selected source/drain region connected to the frontside contact is not included in the pair of source/drain regions connected to the backside via contact.

8. The semiconductor device of claim 1, further comprising a frontside contact connected to at least one of the pair of source/drain regions connected to the backside via contact.

9. The semiconductor device of claim 8, wherein the frontside contact is aligned with the pair of first portions of the backside via contact in the vertical direction.

10. The semiconductor device of claim 8, wherein the frontside contact is a contact commonly connected to the pair of source/drain regions and is aligned with the pair of first portions and the second portion of the backside via contact in the vertical direction.

11. A semiconductor device comprising:
a plurality of gate lines that are neighboring one another in a first horizontal direction and each extend in a second horizontal direction substantially perpendicular to the first horizontal direction;
a plurality of source/drain regions arranged adjacent to the plurality of gate lines in the first horizontal direction, respectively;
a first backside via contact connected to a first pair of source/drain regions that face one another in the second horizontal direction among the plurality of source/drain regions;
a second backside via contact spaced apart from the first backside via contact in the first horizontal direction and connected to a second pair of source/drain regions that face one another in the second horizontal direction among the plurality of source/drain regions;
a plurality of backside insulating patterns aligned with the plurality of gate lines in a vertical direction;
a plurality of semiconductor blocks contacting sidewalls of the plurality of backside insulating patterns in the first horizontal direction; and
a device isolation layer covering sidewalls of the backside via contact in the second horizontal direction,
wherein the first backside via contact comprises a pair of first portions facing the first pair of source/drain regions, and a second portion arranged between the first pair of source/drain regions, and
a first horizontal width of the pair of first portions in the first horizontal direction is less than a second horizontal width of the second portion in the first horizontal direction.

12. The semiconductor device of claim 11, wherein the second backside via contact has a third horizontal width in the first horizontal direction in a plan view, and the third horizontal width is less than the second horizontal width.

13. The semiconductor device of claim 11, wherein:
the pair of first portions of the first backside via contact are in contact with the semiconductor block in the first horizontal direction, and
the second portion of the first backside via contact is in contact with the device isolation layer and some of the plurality of backside insulating patterns in the first horizontal direction.

14. The semiconductor device of claim 11, wherein:
the second backside via contact comprises third portions corresponding to the pair of first portions of the first backside via contact in the first horizontal direction, and a fourth portion corresponding to the second portion of the first backside via contact in the first horizontal direction, and
the third portions of the second backside via contact are in contact with the plurality of semiconductor blocks in the first horizontal direction, and the fourth portion of the second backside via contact is in contact with the device isolation layer, but is spaced apart from the plurality of backside insulating patterns.

15. The semiconductor device of claim 11, wherein upper surfaces of the pair of first portions of the first backside via contact are at a same vertical level as a vertical level of upper surfaces of the pair of first portions of the second backside via contact.

16. The semiconductor device of claim 11, wherein an upper surface of the second portion of the first backside via contact is at a higher vertical level than a vertical level of an upper surface of the second portion of the second backside via contact.

17. The semiconductor device of claim 11, wherein a vertical height of the second portion of the first backside via contact is greater than a vertical height of the second portion of the second backside via contact.

18. A semiconductor device comprising:
a plurality of gate lines that are neighboring one another in a first horizontal direction and each extend in a second horizontal direction substantially perpendicular to the first horizontal direction;
a plurality of source/drain regions arranged adjacent to the plurality of gate lines in the first horizontal direction, respectively;
a backside via contact connected to any one pair of source/drain regions that face one another in the second horizontal direction among the plurality of source/drain regions;
a frontside contact connected to one selected from among the plurality of source/drain regions;
a plurality of backside insulating patterns aligned with the plurality of gate lines in a vertical direction and spaced apart from one another in the first horizontal direction;
a plurality of semiconductor blocks contacting sidewalls of the plurality of backside insulating patterns in the first horizontal direction; and
a device isolation layer covering sidewalls of the backside via contact in the second horizontal direction,
wherein the backside via contact comprises a pair of first portions that face the pair of source/drain regions, and a second portion arranged between the pair of first portions, and
a first horizontal width of the pair of first portions in the first horizontal direction is less than a second horizontal width of the second portion in the first horizontal direction.

19. The semiconductor device of claim 18, wherein:
the pair of first portions are in contact with the plurality of semiconductor blocks in the first horizontal direction, and
the second portion is in contact with the device isolation layer and a portion of the backside insulating pattern in the first horizontal direction.

20. The semiconductor device of claim 18, wherein the selected source/drain region connected to the frontside contact is not included in the pair of source/drain regions connected to the backside via contact.
